(19) United States
(12) Patent Application Publication
(10) Pub. No.: US 2023/0413556 A1
(43) Pub. Date: Dec. 21, 2023

(54) SEMICONDUCTOR MEMORY DEVICE

(71) Applicant: Kioxia Corporation, Tokyo (JP)

(72) Inventor: Yasushi MURAKAMI, Yokkaichi (JP)

(73) Assignee: Kioxia Corporation, Tokyo (JP)

(21) Appl. No.: 18/181,100

(22) Filed: Mar. 9, 2023

(30) Foreign Application Priority Data
Jun. 21, 2022 (JP) 2022-099646

(51) Int. Cl. H10B 43/27; H10B 41/27

(52) U.S. Cl. CPC H10B 43/27; H10B 41/27

(57) ABSTRACT

A semiconductor memory device includes: conductive layers stacked in a stacking direction; a semiconductor layer opposed to the conductive layers; contact electrodes connected to the conductive layers; and insulating members including outer peripheral surfaces surrounded by at least a part of the conductive layers. A first insulating member overlaps with a first contact electrode when viewed from the stacking direction. A second insulating member does not overlap with the contact electrodes when viewed from the stacking direction. A surface on one side in the stacking direction of the first contact electrode is in contact with a first conductive layer and the first insulating member. Insides of surfaces surrounding the second insulating member of at least a part of the conductive layers when viewed from the stacking direction are not provided with a conductive member or a semiconductor member.

### CROSS-REFERENCE TO RELATED APPLICATIONS

This application is based upon and claims the benefit of Japanese Patent Application No. 2022-099646, filed on Jun. 21, 2022, the entire contents of which are incorporated herein by reference.

### FIELD

### Background

Embodiments described herein relate generally to a semiconductor memory device.

### Description of the Related Art

There has been known a semiconductor memory device including a substrate, a plurality of conductive layers stacked in a stacking direction intersecting with a surface of this substrate, a semiconductor layer opposed to these plurality of conductive layers, and a gate insulating film disposed between the plurality of conductive layers and the semiconductor layer. The gate insulating film includes a memory portion configured to store data, and the memory portion is, for example, an insulating electric charge accumulating film of silicon nitride (SiN) or the like, or a conductive electric charge accumulating film or the like, such as a floating gate.

### BRIEF DESCRIPTION OF THE DRAWINGS

FIG. 1 is a schematic plan view of a semiconductor memory device according to a first embodiment;

FIG. 2 is a schematic plan view of the semiconductor memory device;

FIG. 3 is a schematic cross-sectional view of a structure illustrated in FIG. 2 taken along a line A-A′ and viewed in an arrow direction;

FIG. 4 is a schematic enlarged view of a part indicated by B in FIG. 3;

FIG. 5 is a schematic plan view of the semiconductor memory device;

FIG. 6 is a schematic plan view of the semiconductor memory device;

FIG. 7 is a schematic cross-sectional view of a structure illustrated in FIG. 5 and FIG. 6 taken along a line C-C′ and a line D-D′ and viewed in an arrow direction;

FIG. 8 is a schematic cross-sectional view illustrating a manufacturing method of the semiconductor memory device;

FIG. 9 is a schematic cross-sectional view illustrating the manufacturing method;

FIG. 10 is a schematic cross-sectional view illustrating the manufacturing method;

FIG. 11 is a schematic cross-sectional view illustrating the manufacturing method;

FIG. 12 is a schematic cross-sectional view illustrating the manufacturing method;

FIG. 13 is a schematic cross-sectional view illustrating the manufacturing method;

FIG. 14 is a schematic cross-sectional view illustrating the manufacturing method;

FIG. 15 is a schematic cross-sectional view illustrating the manufacturing method;

FIG. 16 is a schematic cross-sectional view illustrating the manufacturing method;

FIG. 17 is a schematic cross-sectional view illustrating the manufacturing method;

FIG. 18 is a schematic cross-sectional view illustrating the manufacturing method;

FIG. 19 is a schematic cross-sectional view illustrating the manufacturing method;

FIG. 20 is a schematic cross-sectional view illustrating the manufacturing method;

FIG. 21 is a schematic cross-sectional view illustrating the manufacturing method;

FIG. 22 is a schematic cross-sectional view illustrating the manufacturing method;

FIG. 23 is a schematic cross-sectional view illustrating the manufacturing method;

FIG. 24 is a schematic cross-sectional view illustrating the manufacturing method;

FIG. 25 is a schematic cross-sectional view illustrating the manufacturing method;

FIG. 26 is a schematic cross-sectional view illustrating a configuration of a semiconductor memory device according to a comparative example;

FIG. 27 is a schematic plan view illustrating a configuration of a semiconductor memory device according to a second embodiment;

FIG. 28 is a schematic cross-sectional view of a structure illustrated in FIG. 27 taken along a line C-C′ and a line D-D′ and viewed in an arrow direction;

FIG. 29 is a schematic cross-sectional view illustrating a manufacturing method of the semiconductor memory device;

FIG. 30 is a schematic cross-sectional view illustrating the manufacturing method;

FIG. 31 is a schematic cross-sectional view illustrating the manufacturing method;

FIG. 32 is a schematic plan view illustrating a configuration of a semiconductor memory device according to a third embodiment;

FIG. 33 is a schematic cross-sectional view of a structure illustrated in FIG. 32 taken along a line C-C′ and a line D-D′ and viewed in an arrow direction;

FIG. 34 is a schematic cross-sectional view illustrating a manufacturing method of the semiconductor memory device;

FIG. 35 is a schematic cross-sectional view illustrating the manufacturing method;

FIG. 36 is a schematic cross-sectional view illustrating the manufacturing method;

FIG. 37 is a schematic cross-sectional view illustrating a manufacturing method of a semiconductor memory device according to another embodiment;

FIG. 38 is a schematic cross-sectional view illustrating the manufacturing method;

FIG. 39 is a schematic cross-sectional view illustrating the manufacturing method; and

FIG. 40 is a schematic cross-sectional view illustrating a configuration of the semiconductor memory device according to the other embodiment.

### DETAILED DESCRIPTION

A semiconductor memory device according to one embodiment comprises: a substrate including a first region and a second region arranged in a first direction; a plurality of conductive layers stacked in a stacking direction intersecting with a surface of the substrate and extending in the first direction across the first region and the second region; a semiconductor layer disposed in the first region, extending in the stacking direction, and opposed to the plurality of conductive layers; an electric charge accumulating film disposed between the plurality of conductive layers and the semiconductor layer; a plurality of contact electrodes disposed in the second region and connected to a plurality of terrace portions of the plurality of conductive layers arranged in the first direction via parts of outer edges of the plurality of conductive layers when viewed from the stacking direction; and a plurality of insulating members disposed in the second region and including outer peripheral surfaces surrounded by at least a part of the plurality of conductive layers when viewed from the stacking direction. The plurality of insulating members include a first insulating member that overlaps with a first contact electrode of the plurality of contact electrodes when viewed from the stacking direction, and a second insulating member that does not overlap with any of the plurality of contact electrodes when viewed from the stacking direction. A surface on one side in the stacking direction of the first contact electrode includes a contact surface in contact with a first conductive layer of the plurality of conductive layers and a contact surface in contact with the first insulating member. Insides of surfaces surrounding the second insulating member of at least a part of the plurality of conductive layers when viewed from the stacking direction are not provided with a conductive member or a semiconductor member.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in OFF state, the first transistor is “electrically connected” to the third transistor.

In this specification, a direction parallel to a surface of the substrate is referred to as an X-direction, a direction parallel to the surface of the substrate and perpendicular to the X-direction is referred to as a Y-direction, and a direction perpendicular to the surface of the substrate is referred to as a Z-direction.

In this specification, a direction intersecting with the surface of the substrate may be referred to as a stacking direction. A direction along a predetermined plane intersecting with the stacking direction may be referred to as a first direction, and a direction intersecting with the first direction along this surface may be referred to as a second direction. The stacking direction may coincide with the Z-direction and need not coincide with this direction. The first direction and the second direction may correspond to any of the X-direction and the Y-direction, and need not correspond to these directions.

Expressions such as “above” and “below” in this specification are based on the substrate. For example, a direction away from the substrate along the above-described Z-direction is referred to as above and a direction approaching the substrate along the Z-direction is referred to as below. A lower surface and a lower end of a certain configuration mean a surface and an end portion at the substrate side of this configuration. An upper surface and an upper end of a certain configuration mean a surface and an end portion at a side opposite to the substrate of this configuration. A surface intersecting with the X-direction or the Y-direction is referred to as a side surface and the like.

### First Embodiment

[Configuration]

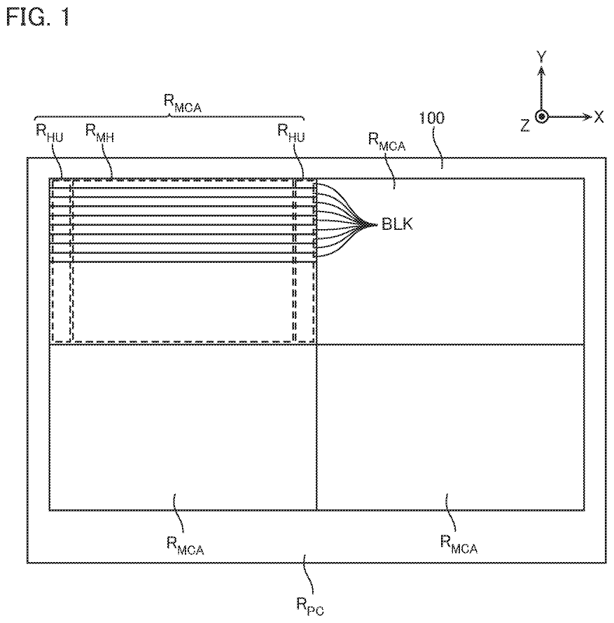

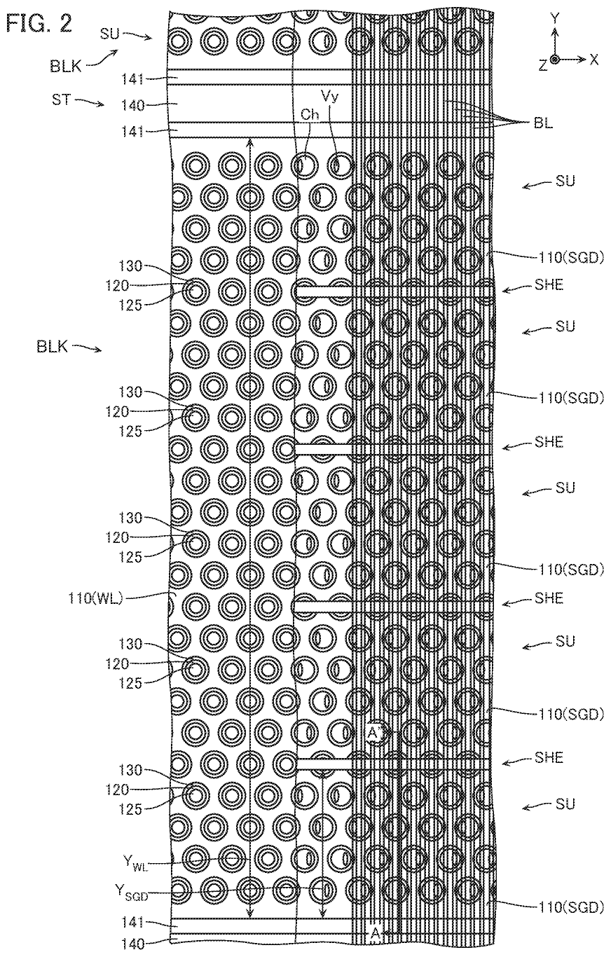

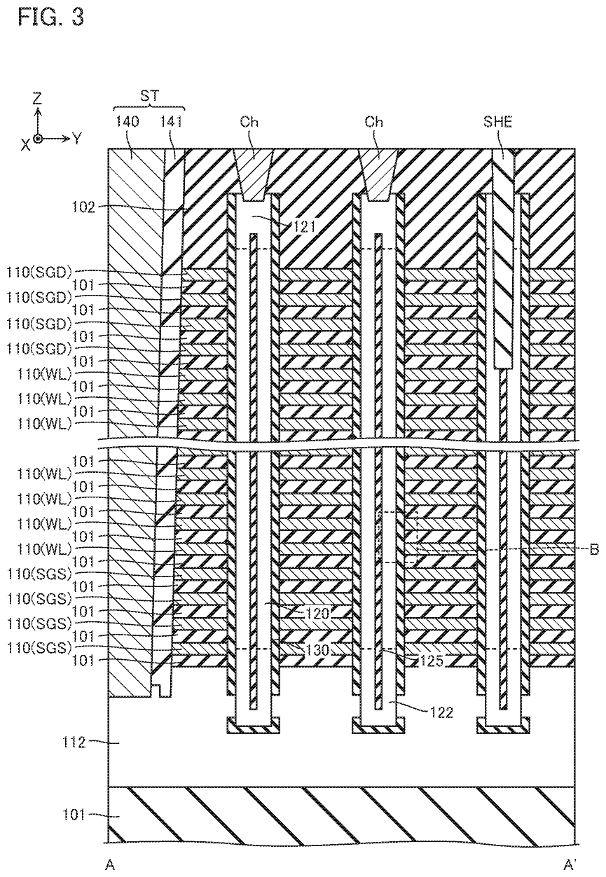

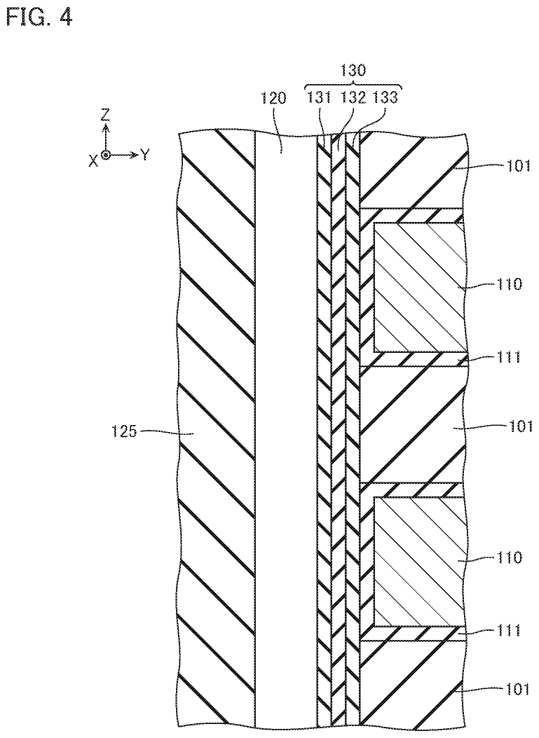

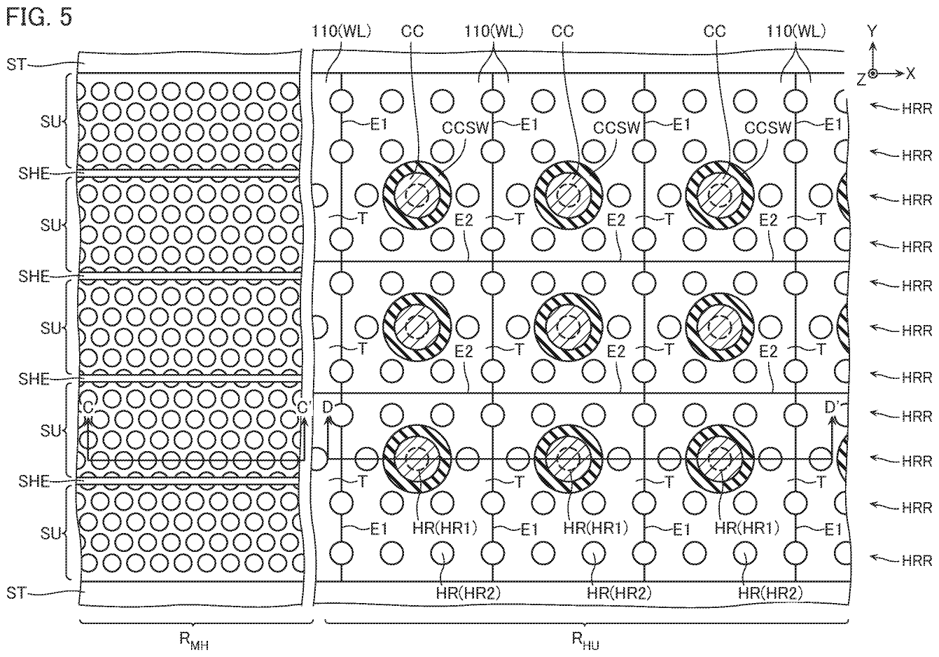

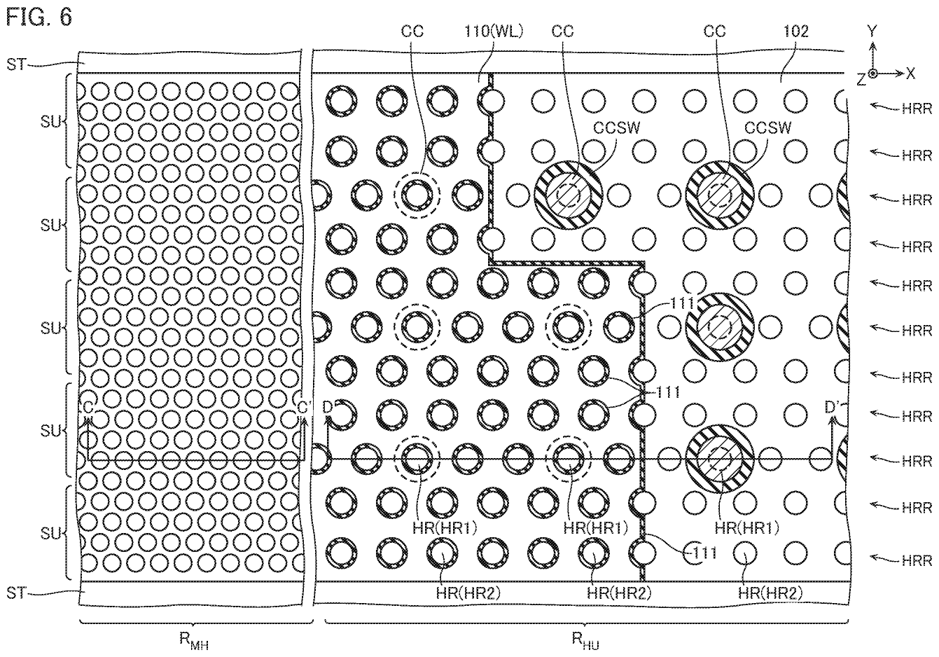

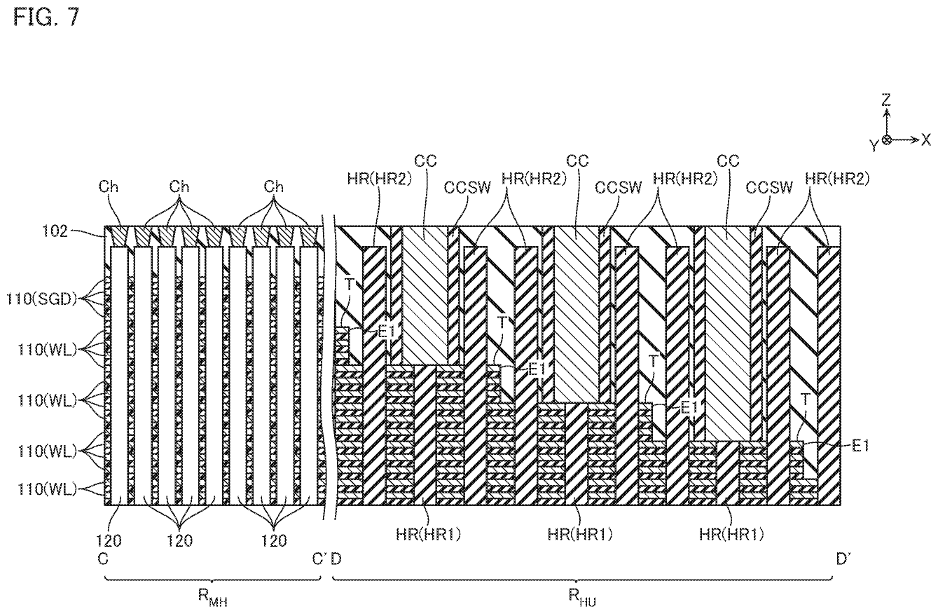

FIG. 1 is a schematic plan view of a semiconductor memory device according to a first embodiment. FIG. 2 is a schematic plan view of the semiconductor memory device, and illustrates an enlarged part in FIG. 1. FIG. 3 is a schematic cross-sectional view of a structure illustrated in FIG. 2 taken along a line A-A′ and viewed in an arrow direction. FIG. 4 is a schematic enlarged view of a part indicated by B in FIG. 3. Note that, while FIG. 4 illustrates a YZ cross-sectional surface, a structure similar to the one in FIG. 4 is observed when observing a cross-sectional surface along a central axis of a semiconductor layer 120 other than the YZ cross-sectional surface (for example, an XZ cross-sectional surface). FIG. 5 is a schematic plan view of the semiconductor memory device, and illustrates an enlarged part in FIG. 1. Note that FIG. 5 omits a part of configurations such as an insulating layer 102 described later. FIG. 6 is a schematic plan view of the semiconductor memory device. A range in the X-direction and the Y-direction in FIG. 6 corresponds to a range in the X-direction and the Y-direction in FIG. 5. FIG. 6 illustrates an XY cross-sectional surface corresponding to a height position of a certain conductive layer 110. Note that, for sake of convenience, FIG. 6 illustrates high-dielectric-constant insulating layers 111 disposed in a hook-up region R_{HU}, and omits the high-dielectric-constant insulating layers 111 disposed in a memory hole region R_{MH}. FIG. 7 is a schematic cross-sectional view of a structure illustrated in FIG. 5 and FIG. 6 taken along a line C-C″ and a line D-D″ and viewed in an arrow direction.

As illustrated in FIG. 1, the semiconductor memory device according to the embodiment includes a semiconductor substrate 100. In the illustrated example, the semiconductor substrate 100 is provided with four memory cell array regions R_{MCA} arranged in the X-direction and the Y-direction. The memory cell array region R_{MCA} is provided with the memory hole region R_{MH} and the hook-up regions R_{HU} disposed in regions in an X-direction positive side and an X-direction negative side with respect to the memory hole region R_{MH}. In addition, an end portion in the Y-direction of the semiconductor substrate 100 is provided with a peripheral circuit region R_{PC}.

Note that, in the illustrated example, the hook-up region R_{HU} is disposed at both end portions in the X-direction of the memory cell array region R_{MCA}. However, such configuration is merely an example, and a specific configuration is appropriately adjustable. For example, the hook-up region R_{HU} may be disposed at both end portions or at one end portion in the X-direction of the memory cell array region R_{MCA}, or may be disposed in a central portion in the X-direction of the memory cell array region R_{MCA}.

The memory cell array region R_{MCA} includes a plurality of memory blocks BLK arranged in the Y-direction. As illustrated in FIG. 2, for example, the memory block BLK includes a plurality of string units SU arranged in the Y-direction. Between two memory blocks BLK mutually adjacent in the Y-direction, an inter-block structure ST is disposed. In addition, between two string units SU mutually adjacent in the Y-direction, an inter-string unit insulating layer SHE of silicon oxide (SiO₂) or the like is disposed.

[Structure of Memory Hole Region R_{MH}]

As illustrated in FIG. 3, for example, the memory block BLK includes a plurality of conductive layers 110 arranged in the Z-direction, a wiring layer 112 disposed below these plurality of conductive layers 110, a plurality of semiconductor layers 120 extending in the Z-direction, and gate insulating films 130 disposed between the plurality of conductive layers 110 and the plurality of semiconductor layers 120.

The conductive layer 110 has an approximately plate shape extending in the X-direction. The conductive layer 110 may include, for example, a stacked film of a barrier conductive film of titanium nitride (TiN) or the like and a metal film of tungsten (W) or the like. The conductive layer 110 may contain, for example, polycrystalline silicon containing impurities, such as phosphorus (P) or boron (B). Between the plurality of conductive layers 110 arranged in the Z-direction, insulating layers 101 of silicon oxide (SiO₂) or the like are disposed. In addition, on an upper surface of the uppermost layer of the conductive layers 110, the insulating layer 102 of silicon oxide (SiO₂) or the like is disposed.

The plurality of conductive layers 110 function as word lines WL of a NAND flash memory and gate electrodes of a plurality of memory cells (memory transistors) connected to the word lines WL of the NAND flash memory. In the following description, such conductive layers 110 may be referred to as conductive layers 110 (WL) in some cases. These plurality of conductive layers 110 (WL) are each electrically independent for each memory block BLK. When focusing on two memory blocks BLK mutually adjacent in the Y-direction, a plurality of the conductive layers 110 (WL) arranged in the Z-direction and a plurality of the insulating layers 101 disposed on upper surfaces and lower surfaces thereof in these two memory blocks BLK are separated in the Y-direction via the inter-block structure ST.

One or a plurality of the conductive layers 110 positioned below the plurality of conductive layers 110 (WL) function as a source-side select gate line SGS of the NAND flash memory and gate electrodes of a plurality of select transistors connected to the source-side select gate line SGS of the NAND flash memory. In the following description, such conductive layer 110 may be referred to as a conductive layer 110 (SGS) in some cases. When focusing on two memory blocks BLK mutually adjacent in the Y-direction, one or a plurality of the conductive layers 110 (SGS) and a plurality of the insulating layers 101 disposed on upper surfaces and lower surfaces thereof in these two memory blocks BLK are separated in the Y-direction via the inter-block structure ST.

One or a plurality of the conductive layers 110 positioned above the plurality of conductive layers 110 (WL) each function as a drain-side select gate line SGD of the NAND flash memory and gate electrodes of a plurality of select transistors connected to the drain-side select gate line SGD of the NAND flash memory. In the following description, such conductive layer 110 may be referred to as a conductive layer 110 (SGD) in some cases.

As illustrated in FIG. 2, a width Y_{SGD} in the Y-direction of these plurality of conductive layers 110 (SGD) is smaller than a width Y_{WL} in the Y-direction of the conductive layers 110 (WL).

The plurality of conductive layers 110 (SGD) are each electrically independent for each string unit SU. In each memory block BLK, when focusing on two string units SU mutually adjacent in the Y-direction, one or a plurality of the conductive layers 110 (SGD) in one of these two string units SU is separated from that of the other of these two string units SU in the Y-direction via the inter-string unit insulating layer SHE. When focusing on one of the plurality of string units SU included in one of two memory blocks BLK mutually adjacent in the Y-direction that is closest to the other of the two memory blocks BLK and one of the plurality of string units SU included in the other of the two memory blocks BLK that is closest to the one of the two memory blocks BLK, one or a plurality of the conductive layers 110 (SGD) in one of these two string units SU is separated from that of the other of these two string units SU in the Y-direction via the inter-block structure ST.

As illustrated in FIG. 4, a high-dielectric-constant insulating layer 111 is disposed on an upper surface, a lower surface, and an opposed surface to the semiconductor layer 120 of the conductive layer 110. The high-dielectric-constant insulating layer 111 contains, for example, a metal oxide, such as alumina (Al₂O₃). The high-dielectric-constant insulating layer 111 has a dielectric constant that is larger than that of, for example, silicon oxide (SiO₂). The high-dielectric-constant insulating layer 111 also has a dielectric constant that is larger than that of, for example, silicon nitride (SiN).

The wiring layer 112 (FIG. 3) may contain, for example, polycrystalline silicon containing N-type impurities, such as phosphorus (P) or the like. In addition, a lower surface of the wiring layer 112 may be provided with a metal, such as tungsten (W), a conductive member, such as tungsten silicide, or other conductive members. The wiring layer 112 functions as a part of a source line of the NAND flash memory.

As illustrated in FIG. 2, the semiconductor layers 120 are arranged in a predetermined pattern in the X-direction and the Y-direction. The semiconductor layers 120 function as channel regions of memory cells (memory transistors) of the NAND flash memory and channel regions of the select transistors of the NAND flash memory. The semiconductor layer 120 has an approximately cylindrical shape, and its center part is provided with an insulating layer 125 of silicon oxide or the like. In addition, outer peripheral surfaces of the semiconductor layers 120 are surrounded by respective through holes disposed in the conductive layers 110, and are opposed to inner peripheral surfaces of such through holes.

The semiconductor layer 120 contains, for example, polycrystalline silicon (Si) or the like. A region opposed to the conductive layers 110 (WL) of the semiconductor layer 120 may be non-doped. A region opposed to the conductive layers 110 (SGD) of the semiconductor layer 120 may be non-doped or may contain P-type impurities, such as boron (B) or the like. At least a part of a region opposed to the conductive layers 110 (SGS) of the semiconductor layer 120 may be non-doped. A part of the region opposed to the conductive layers 110 (SGS) of the semiconductor layer 120 may contain N-type impurities, such as phosphorus (P).

As illustrated in FIG. 3, on an upper end portion of the semiconductor layer 120, an impurity region 121 containing N-type impurities, such as phosphorus (P), is disposed. This impurity region 121 is connected to a bit line BL (FIG. 2) via via-contact electrodes Ch, Vy (FIG. 2). Note that, as illustrated in FIG. 2, a plurality of the semiconductor layers 120 corresponding to one string unit SU are all connected to different bit lines BL. In the example of FIG. 2, four rows including a plurality of the semiconductor layers 120 arranged in the X-direction are arranged in the Y-direction corresponds to one string unit SU. The plurality of semiconductor layers 120 included in these four rows are all connected to different bit lines BL.

As illustrated in FIG. 3, in a lower end portion of the semiconductor layer 120, an impurity region 122 containing N-type impurities, such as phosphorus (P), is disposed. This impurity region 122 is connected to the above-described wiring layer 112. Note that a plurality of the semiconductor layers 120 corresponding to one memory cell array region R_{MCA} (FIG. 1) are all connected to a common wiring layer 112.

The gate insulating film 130 has an approximately cylindrical shape covering the outer peripheral surface of the semiconductor layer 120. As illustrated in FIG. 4, for example, the gate insulating film 130 includes a tunnel insulating film 131, an electric charge accumulating film 132, and a block insulating film 133 stacked between the semiconductor layer 120 and the conductive layers 110. The tunnel insulating film 131 and the block insulating film 133 contain, for example, silicon oxide (SiO₂) or the like. The electric charge accumulating film 132 contains a film configured to accumulate electric charge of, for example, silicon nitride (SiN) or the like. The tunnel insulating film 131, the electric charge accumulating film 132, and the block insulating film 133 have approximately cylindrical shapes, and as illustrated in FIG. 3, for example, extend in the Z-direction along the outer peripheral surface of the semiconductor layer 120 excluding contact portions between the semiconductor layer 120 and the wiring layer 112.

Note that, FIG. 4 illustrates an example in which the gate insulating film 130 includes the electric charge accumulating film 132 of silicon nitride or the like. However, the electric charge accumulating film included in the gate insulating film 130 may be, for example, floating gates of polycrystalline silicon or the like containing N-type or P-type impurities.

As illustrated in FIG. 2 and FIG. 3, for example, the inter-string unit insulating layer SHE extends in the X-direction and the Z-direction. The inter-string unit insulating layer SHE contains, for example, silicon oxide (SiO₂) or the like. A lower end of the inter-string unit insulating layers SHE is positioned above a lower surface of the conductive layer 110 (WL) positioned in the uppermost layer. The lower end of the inter-string unit insulating layer SHE is positioned below a lower surface of the conductive layer 110 (SGD) positioned in the lowermost layer. In addition, a position in the Z-direction of an upper end of the inter-string unit insulating layer SHE is positioned above an upper surface of the conductive layer 110 (SGD) positioned in the uppermost layer.

As illustrated in FIG. 2 and FIG. 3, for example, the inter-block structure ST includes an electrode 140 extending in the X-direction and the Z-direction, and insulating layers 141 of silicon oxide (SiO₂) or the like disposed on both side surfaces in the Y-direction of the electrode 140. The electrode 140 is spaced in the Y-direction from the plurality of conductive layers 110 arranged in the Z-direction, the plurality of insulating layers 101 disposed therebetween, and the insulating layer 102 via the insulating layers 141. Lower ends of the electrode 140 and the insulating layers 141 are connected to the wiring layer 112. The electrode 140 may be, for example, a conductive member including a stacked film of a barrier conductive film of titanium nitride (TiN) or the like and a metal film of tungsten (W) or the like. The electrode 140 may also be, for example, a semiconductor member of polycrystalline silicon or the like containing impurities such as phosphorus (P) or boron (B). The electrode 140 may include both the conductive member and the semiconductor member. The electrode 140 functions as a part of the source line of the NAND flash memory.

As illustrated in FIG. 2, for example, the via-contact electrodes Ch are arranged in a predetermined pattern in the X-direction and the Y-direction, corresponding to the semiconductor layers 120. The via-contact electrode Ch extends in the Z-direction, and has a lower end connected to the impurity region 121 of the semiconductor layer 120 and an upper end connected to the via-contact electrode Vy (FIG. 2).

As illustrated in FIG. 2, the bit lines BL extend in the Y-direction, and are arranged in the X-direction. A pitch in the X-direction of the bit lines BL is a quarter of a pitch in the X-direction of the plurality of semiconductor layers 120 arranged in the X-direction. The bit line BL may include, for example, a stacked film of a barrier conductive film of titanium nitride (TiN) or the like and a metal film of copper (Cu) or the like. The above-described via-contact electrodes Vy are disposed at positions where the bit lines BL and the via-contact electrodes Ch overlap when viewed from the Z-direction.

[Structure of Hook-Up Region R_{HU}]

In the hook-up region R_{HU}, as illustrated in FIG. 5 and FIG. 7, terrace portions T of the plurality of conductive layers 110 are disposed. The terrace portion T is, for example, a part of an upper surface of a conductive layer 110 that does not overlap with the other conductive layers 110 when viewed from above. As illustrated in FIG. 7, these plurality of terrace portions T are covered with the above-described insulating layer 102.

In the illustrated example, a plurality of the terrace portions T corresponding to the 3n+1-th (n is an integer of 0 or more) conductive layers 110 (WL) counted from above are arranged in the X-direction when viewed from above. Further, between the terrace portions T of the 3n+1-th conductive layers 110 (WL) and the terrace portions T of the 3n+4-th conductive layers 110 (WL), parts of outer edges E1 of the 3n+1-th to 3n+3-th conductive layers 110 (WL) are disposed. In the illustrated example, the parts of outer edges E1 are end surfaces in the X-direction of the conductive layers 110, and extend in the Y-direction.

Similarly, in the illustrated example, a plurality of the terrace portions T corresponding to the 3n+2-th conductive layers 110 (WL) counted from above are arranged in the X-direction when viewed from above. In addition, between the terrace portions T of the 3n+2-th conductive layers 110 (WL) and the terrace portions T of the 3n+5-th conductive layers 110 (WL), the parts of outer edges E1 of the 3n+2-th to 3n+4-th conductive layers 110 (WL) are disposed.

Similarly, in the illustrated example, a plurality of the terrace portions T corresponding to the 3n+3-th conductive layers 110 (WL) counted from above are arranged in the X-direction when viewed from above. In addition, between the terrace portions T of the 3n+3-th conductive layers 110 (WL) and the terrace portions T of the 3n+6-th conductive layers 110 (WL), the parts of outer edges E1 of the 3n+3-th to 3n+5-th conductive layers 110 (WL) are disposed.

In addition, in the illustrated example, the respective terrace portions T corresponding to the 3n+1-th conductive layers 110 (WL) counted from above are arranged in the Y-direction with two terrace portions T corresponding to the 3n+2-th and the 3n+3-th conductive layers 110 (WL) when viewed from above. In addition, between the terrace portions T of the 3n+1-th conductive layers 110 (WL) and the terrace portions T of the 3n+2-th conductive layers 110 (WL), parts of outer edges E2 of the 3n+1-th conductive layers 110 (WL) are disposed. Similarly, between the terrace portions T of the 3n+2-th conductive layers 110 (WL) and the terrace portions T of the 3n+3-th conductive layers 110 (WL), the parts of outer edges E2 of the 3n+2-th conductive layers 110 (WL) are disposed. In the illustrated example, the parts of outer edges E2 is an end surface in the Y-direction of the conductive layer 110 (WL), and extends in the X-direction.

In addition, as illustrated in FIG. 5, a plurality of supporting insulating member rows HRR arranged in the Y-direction are disposed in the hook-up region R_{HU}. The respective supporting insulating member rows HRR include a plurality of supporting insulating members HR arranged in the X-direction. The supporting insulating member HR contains, for example, silicon oxide (SiO₂) or the like. As illustrated in FIG. 7, the supporting insulating member HR penetrates the insulating layer 102, and the plurality of conductive layers 110 and the insulating layers 101, and extends in the Z-direction. Respective outer peripheral surfaces of the supporting insulating members HR are surrounded by the through holes disposed in the conductive layers 110. As illustrated in FIG. 6, the outer peripheral surface of the supporting insulating member HR is opposed to the inner peripheral surface of such through hole via the high-dielectric-constant insulating layer 111 described with reference to FIG. 4. However, the outer peripheral surface of the supporting insulating member HR may be in contact with the inner peripheral surface of the through hole. Note that, in the embodiment, neither a conductive member nor a semiconductor member is disposed inside this through hole, and only an insulating member (only the supporting insulating member HR and the high-dielectric-constant insulating layer 111, or only the supporting insulating member HR) is disposed when viewed from the Z-direction.

In addition, as illustrated in FIG. 5, in the hook-up region R_{HU}, a plurality of via-contact electrodes CC disposed corresponding to a plurality of the terrace portions T are disposed. In the example of FIG. 5, the plurality of via-contact electrodes CC are arranged in the X-direction via the parts of outer edges E1 of the conductive layers 110 when viewed from the Z-direction. Corresponding to one memory block BLK, three via-contact electrodes CC are arranged in the Y-direction via the parts of outer edges E2 of the conductive layers 110 when viewed from the Z-direction. The via-contact electrode CC may include, for example, a stacked film of a barrier conductive film of titanium nitride (TiN) or the like and a metal film of tungsten (W) or the like. In addition, on outer peripheral surfaces of these plurality of via-contact electrodes CC, insulating layers CCSW of silicon oxide (SiO₂) or the like are disposed. As illustrated in FIG. 7, the via-contact electrode CC and the insulating layer CCSW penetrate the insulating layer 102, extend in the Z-direction, and have lower ends connected to the terrace portion T of the conductive layer 110.

Note that, FIG. 5 to FIG. 7 exemplify supporting insulating members HR1 and supporting insulating members HR2 as the plurality of supporting insulating members HR. The supporting insulating members HR1 overlap with the via-contact electrodes CC when viewed from the Z-direction. More specifically, at a position on a lower surface of the via-contact electrode CC in contact with the conductive layer 110 and the supporting insulating member HR1, an entire outer peripheral surface of the supporting insulating member HR1 is positioned inside the outer peripheral surface of the via-contact electrode CC when viewed from the Z-direction. In addition, when viewed from the Z-direction, a center position of the supporting insulating member HR1 overlaps (approximately coincides) with a center position of any of the via-contact electrodes CC. On the other hand, the supporting insulating members HR2 do not overlap with the via-contact electrodes CC when viewed from the Z-direction. Therefore, at the position on the lower surface of the via-contact electrode CC in contact with the conductive layer 110 and the supporting insulating member HR1, an entire outer peripheral surface of the supporting insulating member HR2 is positioned outside the outer peripheral surface of the via-contact electrode CC when viewed from the Z-direction. In addition, when viewed from the Z-direction, a center position of the supporting insulating member HR2 does not overlap (does not approximately coincide) with the center position of any of the via-contact electrodes CC.

In addition, in the examples of FIG. 5 to FIG. 7, the plurality of via-contact electrodes CC have parts that overlap with the conductive layer 110 and parts that overlap with the supporting insulating member HR1 when viewed from the Z-direction. A diameter of the lower surfaces of the plurality of via-contact electrodes CC is larger than a diameter of an upper end portion of the supporting insulating member HR1. The respective lower surfaces of the plurality of via-contact electrodes CC include a contact surface in contact with the conductive layer 110 and a contact surface in contact with the supporting insulating member HR1.

Note that, the center positions of the supporting insulating members HR when viewed from the Z-direction may be specified by the following method as an example. For example, in an XY cross-sectional surface at a height position corresponding to any of the conductive layers 110 (for example, a cross section as exemplified in FIG. 6), center points of circumscribed circles of the supporting insulating members HR or centroids on images of the supporting insulating members HR may be specified as the center positions.

In addition, a diameter of the upper end portion of the supporting insulating member HR1 may be specified by the following method as an example. For example, in an XY cross-sectional surface at a height position corresponding to a conductive layer 110 disposed on top among the plurality of conductive layers 110 disposed above a lower end of a focused supporting insulating member HR1 and below an upper end of the focused supporting insulating member HR1, a diameter of a circumscribed circle of the supporting insulating member HR1 may be specified as the diameter of the upper end portion of the supporting insulating member HR1. In addition, in an XZ cross-sectional surface as exemplified in FIG. 7 or a YZ cross-sectional surface, a length in the X-direction or a length in the Y-direction at the height position as described above of the supporting insulating member HR1 may be specified as the diameter of the upper end portion of the supporting insulating member HR1.

In addition, the center position of the via-contact electrode CC when viewed from the Z-direction may be specified by the following method as an example. For example, in an XY cross-sectional surface at a height position above a lower end of a focused via-contact electrode CC and below an upper end of the focused via-contact electrode CC, a center point of a circumscribed circle of the via-contact electrode CC or a centroid on an image of the via-contact electrode CC may be specified as the center position.

[Manufacturing Method]

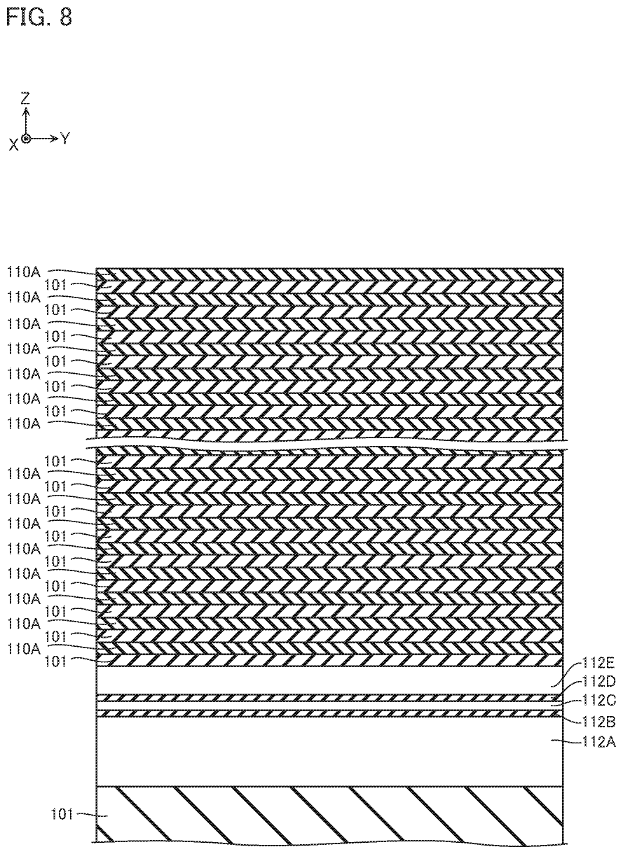

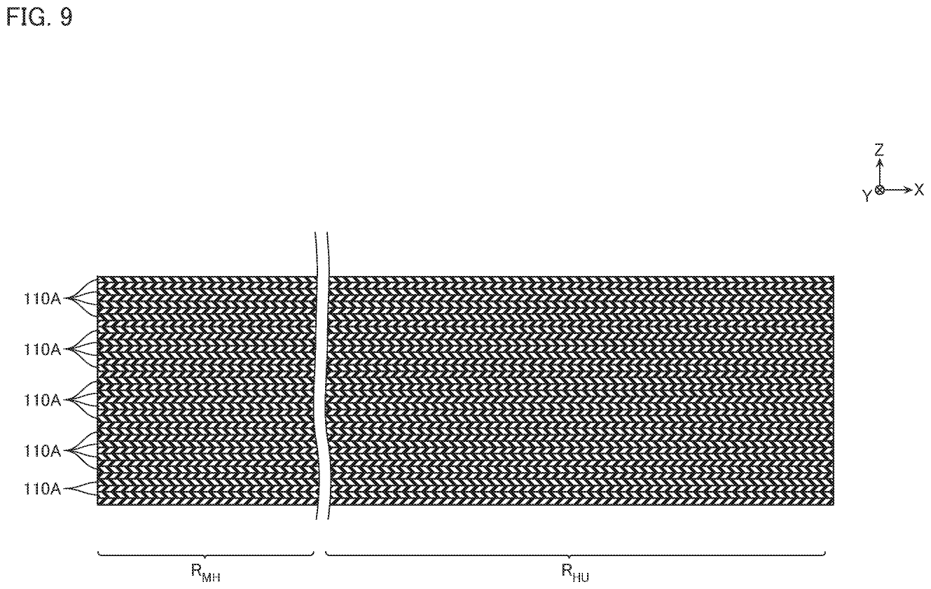

Next, a manufacturing method of the semiconductor memory device according to the first embodiment will be described with reference to FIG. 8 to FIG. 25. FIG. 8 and FIG. 15 to FIG. 21 are schematic cross-sectional views for describing the manufacturing method and illustrate cross-sectional surfaces corresponding to FIG. 3. FIG. 9 to FIG. 14 and FIG. 22 to FIG. 25 are schematic cross-sectional views for describing the manufacturing method and illustrate cross-sectional surfaces corresponding to FIG. 7.

Regarding the manufacturing of the semiconductor memory device according to the embodiment, a peripheral circuit is formed on an upper surface of a semiconductor wafer (not illustrated). Above this semiconductor wafer, as illustrated in FIG. 8, for example, a semiconductor layer 112A of silicon or the like, a sacrifice layer 112B of silicon oxide or the like, a sacrifice layer 112C of silicon nitride (SiN) or the like, a sacrifice layer 112D of silicon oxide or the like, and a semiconductor layer 112E of silicon or the like are formed. In addition, as illustrated in FIG. 8 and FIG. 9, the plurality of insulating layers 101 and a plurality of sacrifice layers 110A are alternately formed. The sacrifice layer 110A contains, for example, silicon nitride (SiN) or the like. This process is performed by a method such as Chemical Vapor Deposition (CVD) or the like.

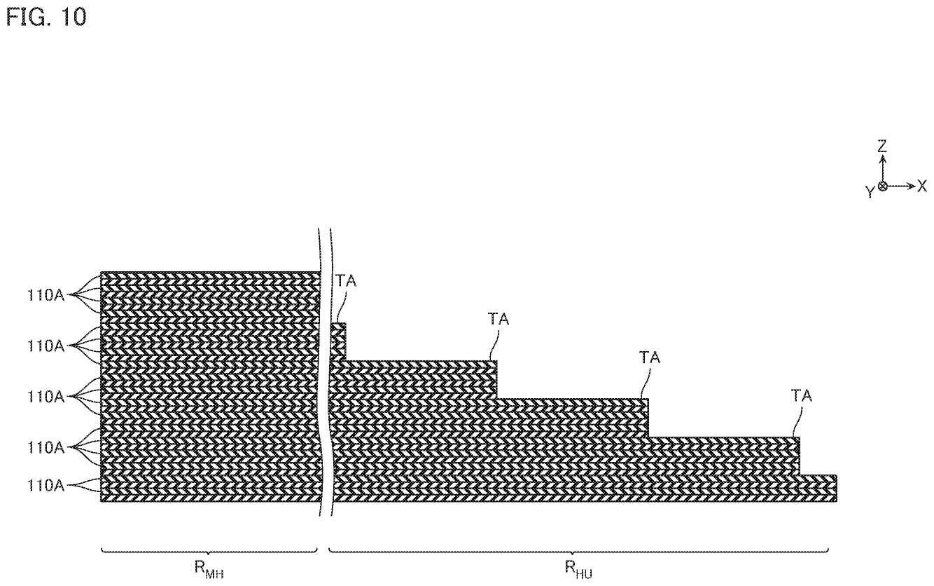

Next, as illustrated in FIG. 10, for example, a part of the plurality of insulating layers 101 and a part of the plurality of sacrifice layers 110A are removed, and a plurality of terrace portions TA are formed in the hook-up regions R_{HU}. The terrace portion TA is, for example, a part of an upper surface of a sacrifice layer 110A that does not overlap with the other sacrifice layers 110A when viewed from above. In this process, for example, a resist is formed on an upper surface of a structure as illustrated in FIG. 9. The removal of the sacrifice layers 110A, the removal of the insulating layers 101, and a partial removal of the resist are repeatedly performed. Note that, the removal of the resist is performed by an isotropic etching such as wet etching.

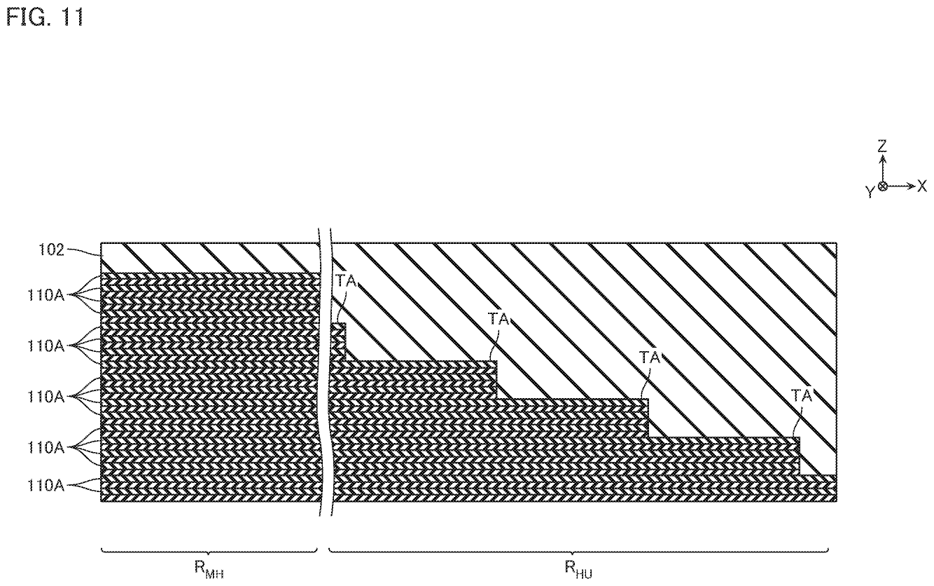

Next, as illustrated in FIG. 11, for example, the insulating layer 102 of silicon oxide (SiO₂) or the like that covers the plurality of terrace portions TA is formed. This process is performed by a method such as CVD or the like.

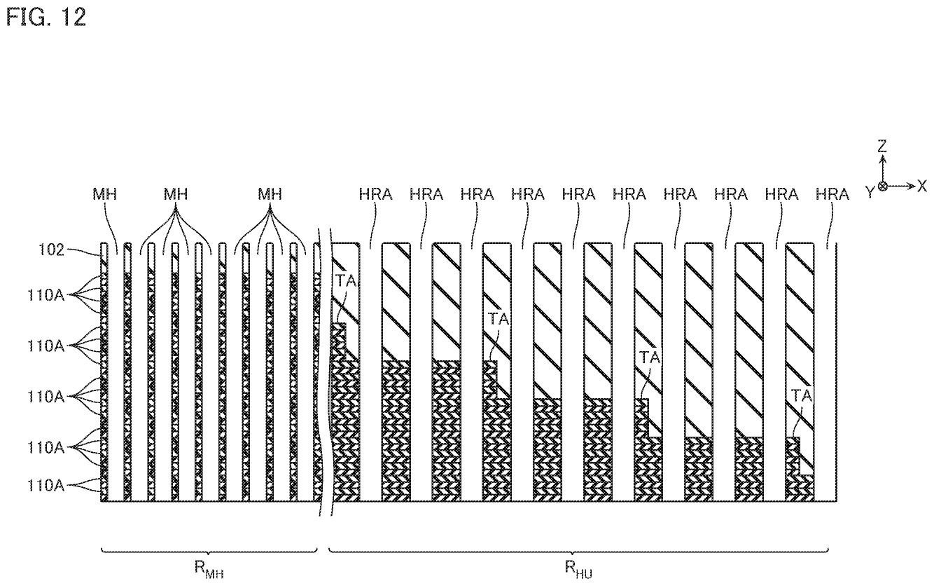

Next, as illustrated in FIG. 12, for example, the plurality of memory holes MH are formed in positions corresponding to the plurality of semiconductor layers 120. In addition, the plurality of via holes HRA are formed in positions corresponding to the plurality of supporting insulating members HR. The memory hole MH and the via hole HRA are each a through hole that extends in the Z-direction, penetrates the insulating layer 101 and the sacrifice layer 110A, the semiconductor layer 112E, the sacrifice layers 112D, 112C, and 112B, and exposes an upper surface of the semiconductor layer 112A. This process is performed by a method such as RIE or the like.

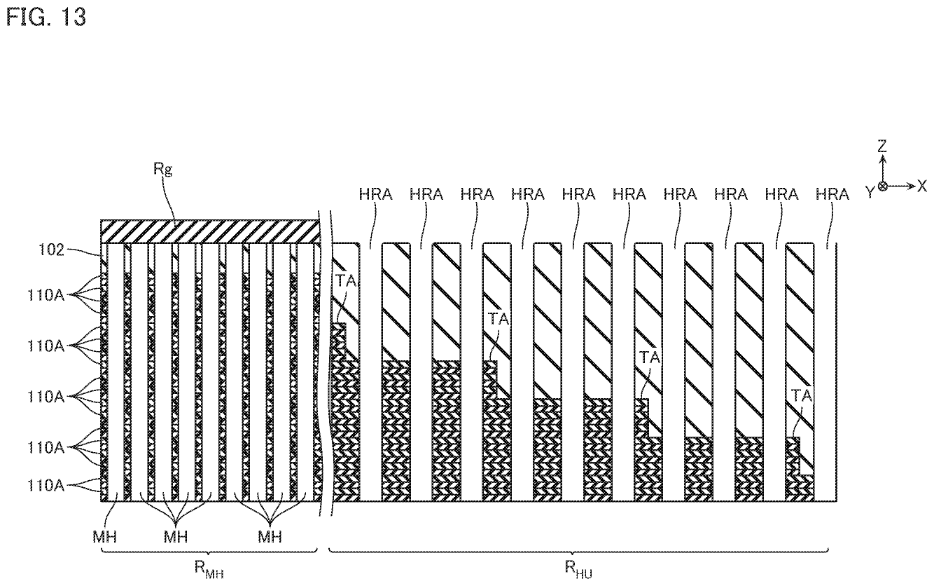

Next, as illustrated in FIG. 13, for example, a resist Rg is formed. Accordingly, a structure in which the plurality of memory holes MH are covered by the resist Rg and the plurality of via holes HRA are exposed is formed.

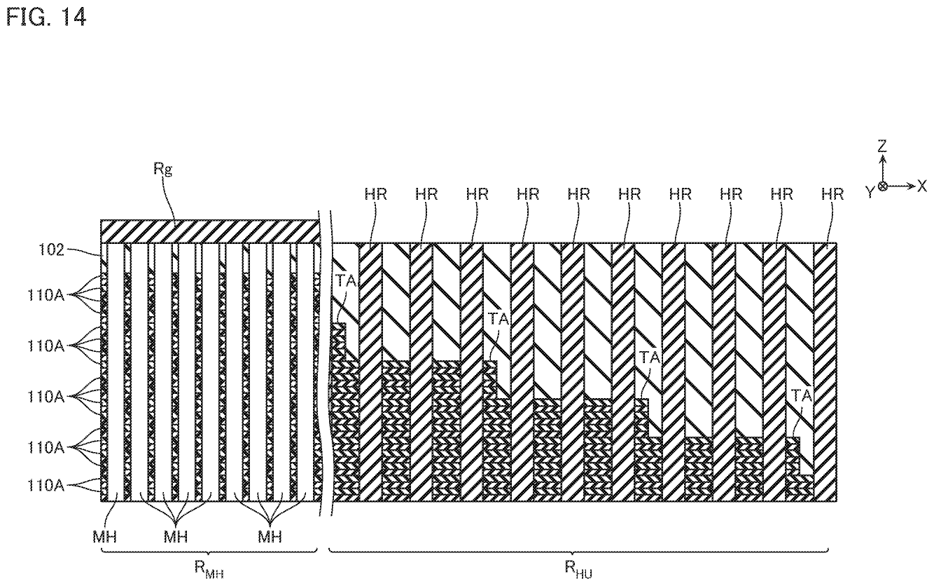

Next, as illustrated in FIG. 14, for example, the supporting insulating members HR are formed inside the plurality of via holes HRA. This process is performed by, for example, CVD and RIE. Further, after forming the supporting insulating members HR, the resist Rg is removed.

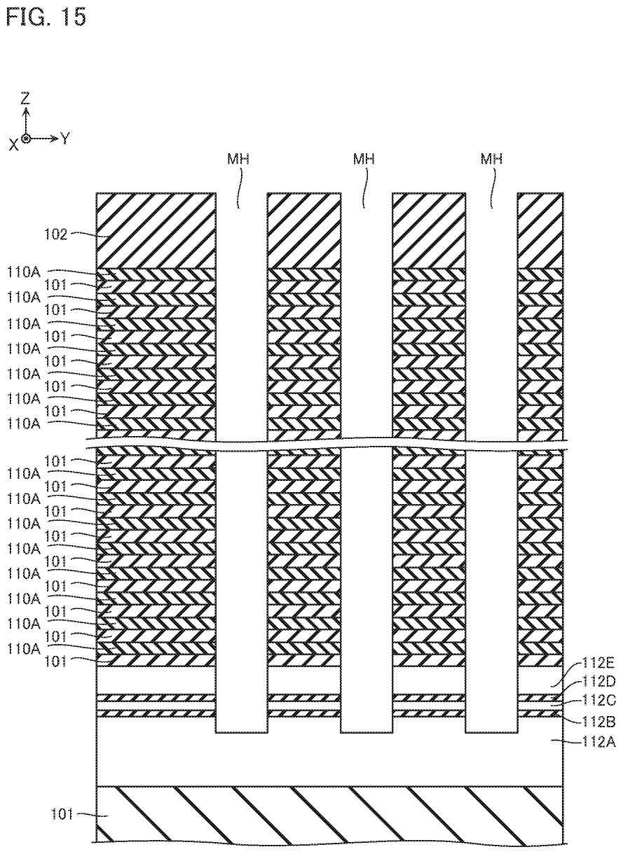

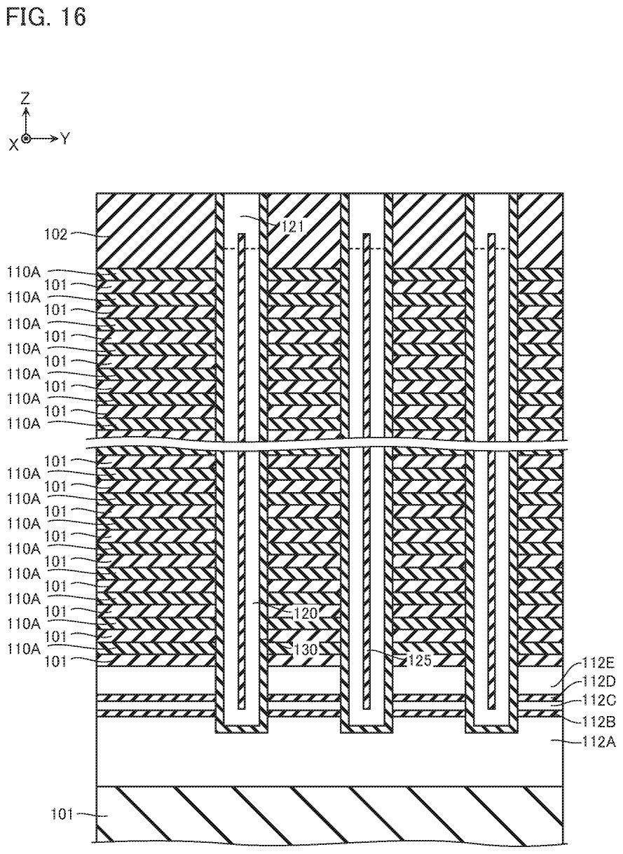

Next, as illustrated in FIG. 15 and FIG. 16, for example, the gate insulating films 130, the semiconductor layers 120, and the insulating layers 125 are formed inside the plurality of memory holes MH. This process is performed by, for example, CVD and RIE.

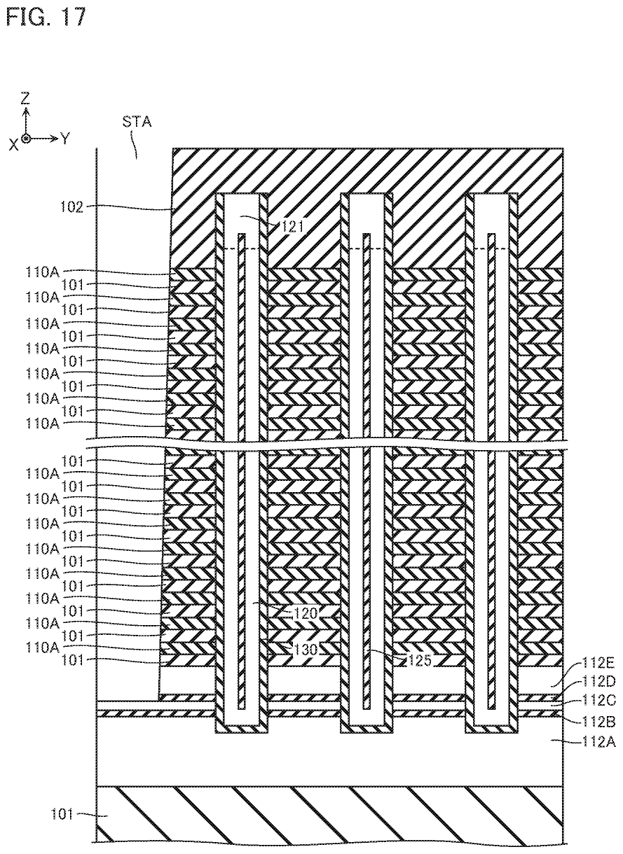

Next, as illustrated in FIG. 17, for example, the insulating layer 102 is formed on an upper surface of a structure as illustrated in FIG. 16. In addition, a trench STA is formed in a position corresponding to the inter-block structure ST. The trench STA extends in the Z-direction and the X-direction, separates the insulating layer 102, the insulating layers 101, the sacrifice layers 110A, the semiconductor layer 112E, and the sacrifice layer 112D in the Y-direction, and exposes an upper surface of the sacrifice layer 112C. This process is performed by a method such as RIE or the like.

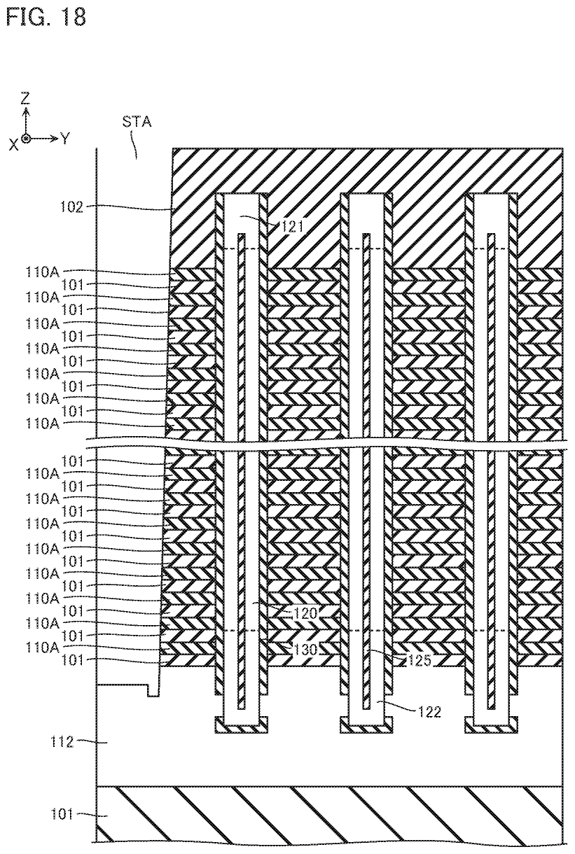

Next, as illustrated in FIG. 18, for example, the wiring layer 112 is formed. In this process, by a method such as wet etching or the like, the sacrifice layers 112B, 112C, and 112D are removed. In addition, by a method such as wet etching, the gate insulating films 130 are partially removed, and the outer peripheral surfaces of the semiconductor layers 120 are partially exposed. Further, the wiring layer 112 is formed by a method such as epitaxial growth.

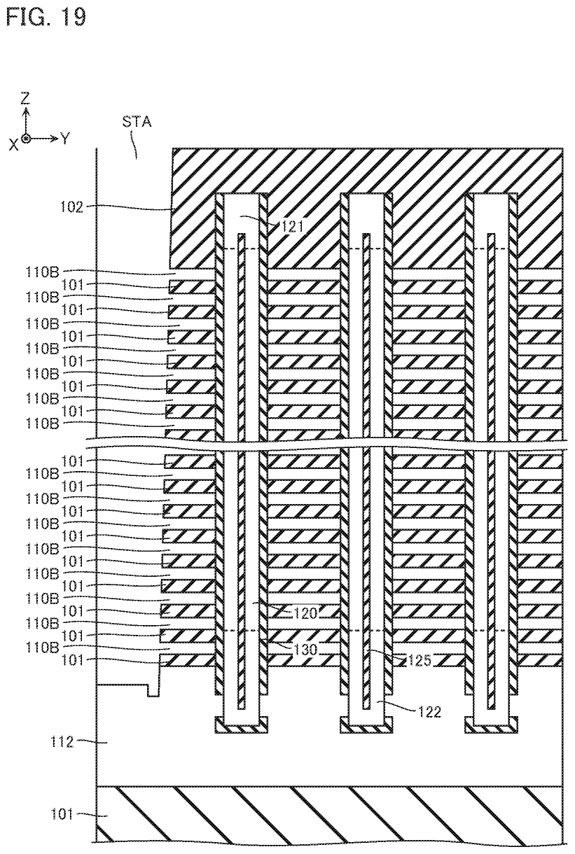

Next, as illustrated in FIG. 19, for example, the sacrifice layers 110A are removed via the trench STA. Accordingly, a plurality of cavities 110B arranged in the Z-direction are formed. In other words, a hollow structure including the plurality of insulating layers 101 arranged in the Z-direction and structures supporting these insulating layers 101 is formed. In the memory hole region R_{MH}, the insulating layers 101 are supported by the structures inside the memory holes MH (the semiconductor layer 120, the gate insulating film 130, and the insulating layer 125). In the hook-up region R_{HU}, the insulating layers 101 are supported by the supporting insulating members HR. This process is performed by a method such as wet etching or the like.

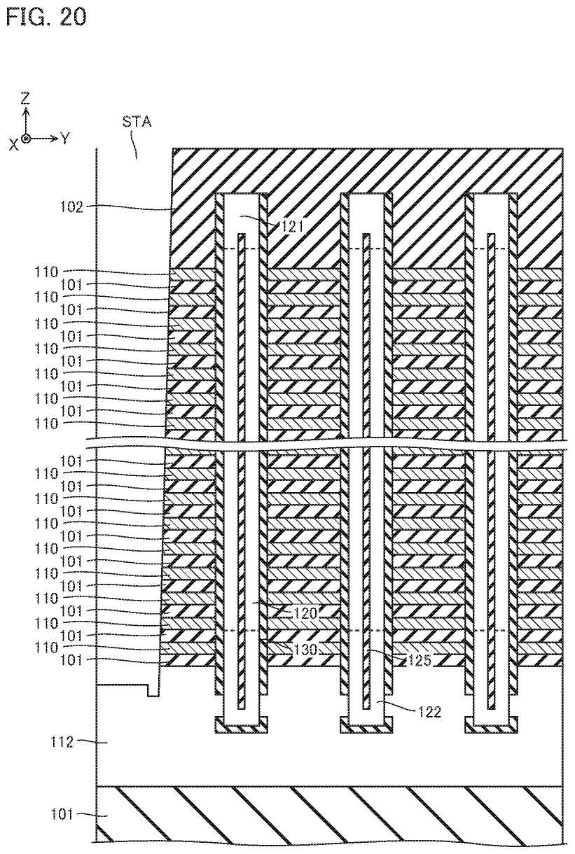

Next, as illustrated in FIG. 20, for example, the plurality of conductive layers 110 are formed in the plurality of cavities 110B arranged in the Z-direction. This process is performed by a method such as CVD or the like. Note that, while illustration is omitted in FIG. 20, in this process, before forming the conductive layers 110 in the cavities 110B, the high-dielectric-constant insulating layers 111 described with reference to FIG. 4 are formed.

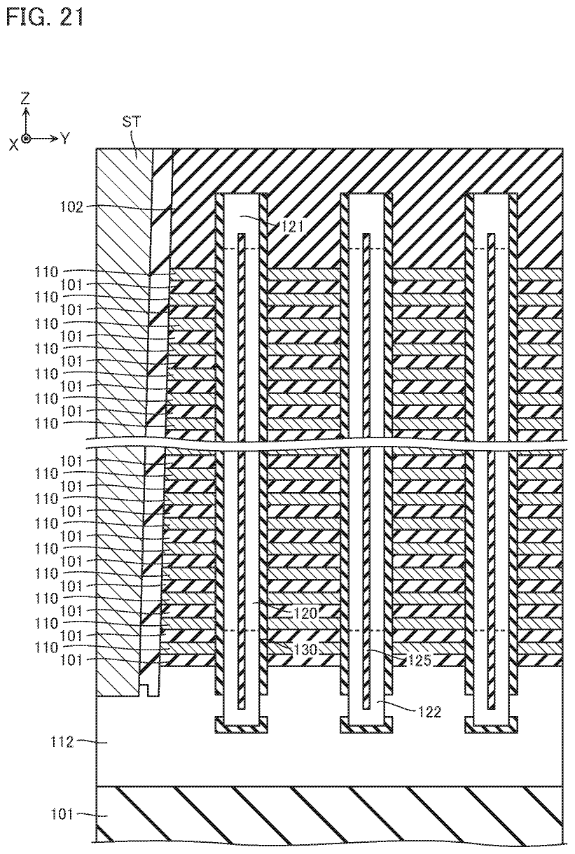

Next, as illustrated in FIG. 21, for example, an inter-block structure ST is formed inside the trench STA. This process is performed by, for example, CVD and RIE. In addition, as illustrated in FIG. 3, the inter-string unit insulating layers SHE that separate one or a plurality of conductive layers 110 (SGD) in the Y-direction are formed. This process is performed by, for example, CVD and RIE.

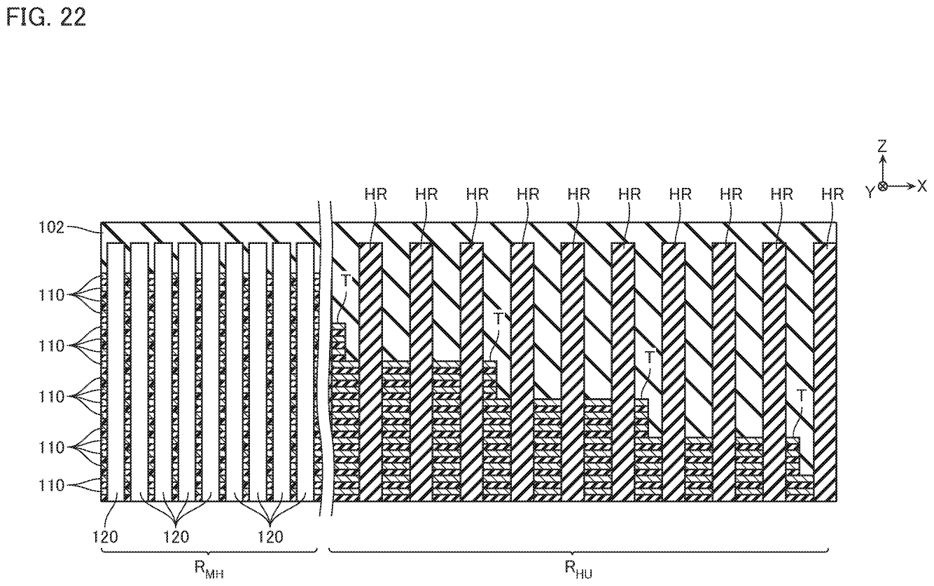

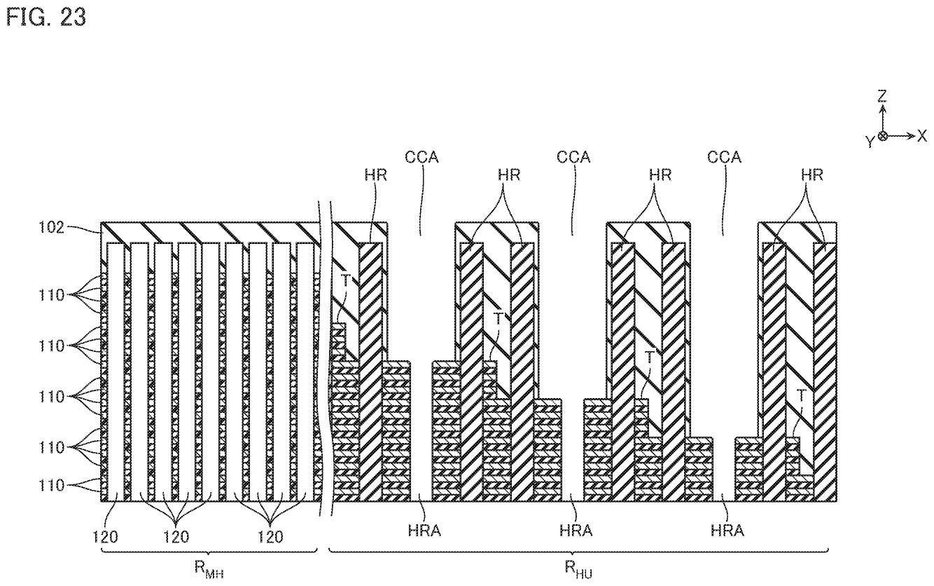

Next, as illustrated in FIG. 22, for example, the insulating layer 102 is formed on an upper surface of a structure corresponding to FIG. 3. In addition, as illustrated in FIG. 23, the plurality of contact holes CCA are formed in positions corresponding to the plurality of via-contact electrodes CC. The respective contact holes CCA extend in the Z-direction, penetrate the insulating layer 102, and expose the terrace portions T of the conductive layers 110. This process is performed by a method such as RIE or the like.

In the manufacturing method according to the embodiment, when forming the contact holes CCA, not only the insulating layer 102 but also the supporting insulating members HR exposed on bottom surfaces of the contact holes CCA are also removed. Accordingly, a part of the plurality of via holes HRA described with reference to FIG. 12 are formed again below the contact holes CCA. Note that, the supporting insulating members HR that are not removed in this process become the supporting insulating members HR2 described with reference to FIG. 5 and FIG. 7.

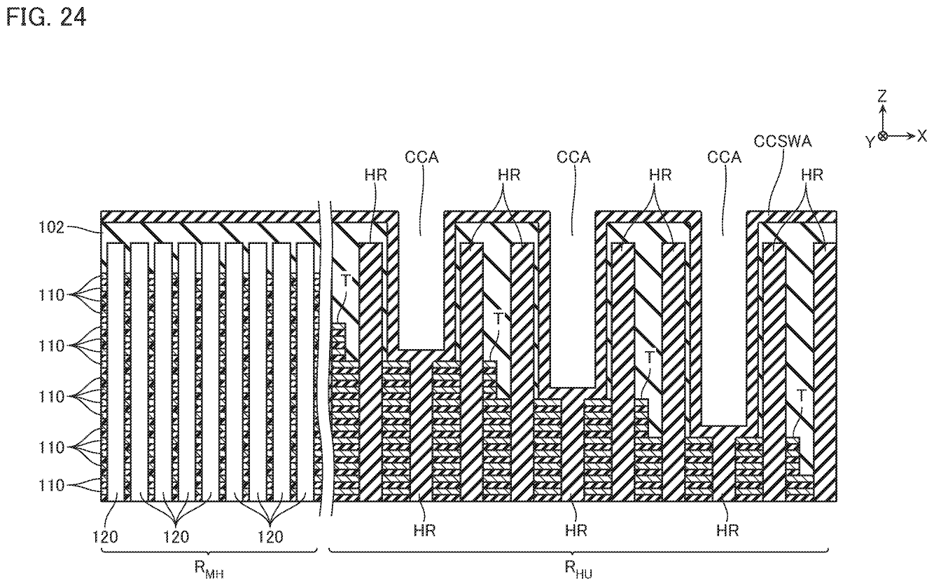

Next, as illustrated in FIG. 24, for example, the insulating layer CCSWA is formed on an upper surface of the insulating layer 102, inner peripheral surfaces and the bottom surfaces of the contact holes CCA, and inside the via holes HRA. The insulating layer CCSWA is thick to the extent of embedding the via holes HRA, and thin to the extent of not embedding the contact holes CCA. This process is performed by a method such as CVD or the like.

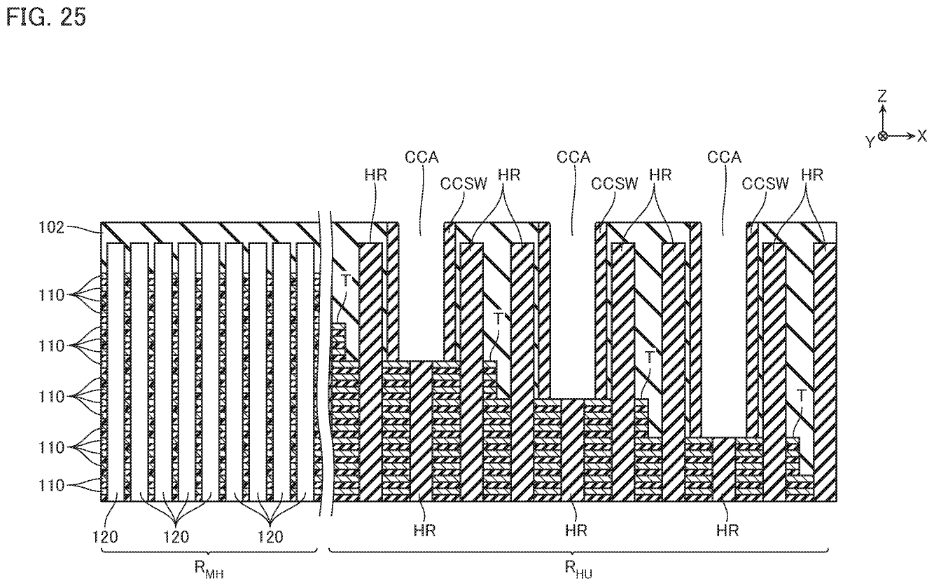

Next, as illustrated in FIG. 25, parts of the insulating layer CCSWA formed on the bottom surfaces of the contact holes CCA are removed to expose the terrace portions T. This process is performed by a method such as RIE or the like. By this process, the supporting insulating members HR1 described with reference to FIG. 5 and FIG. 7 are formed below the contact hole CCA.

Next, as illustrated in FIG. 7, the via-contact electrodes CC are formed inside the contact holes CCA. This process is performed by a method such as CVD or the like.

Subsequently, by forming the via-contact electrodes Ch, Vy and the bit lines BL described with reference to FIG. 2 and the like, and performing individualization by dicing or the like, the semiconductor memory device according to the first embodiment is formed.

### Comparative Example

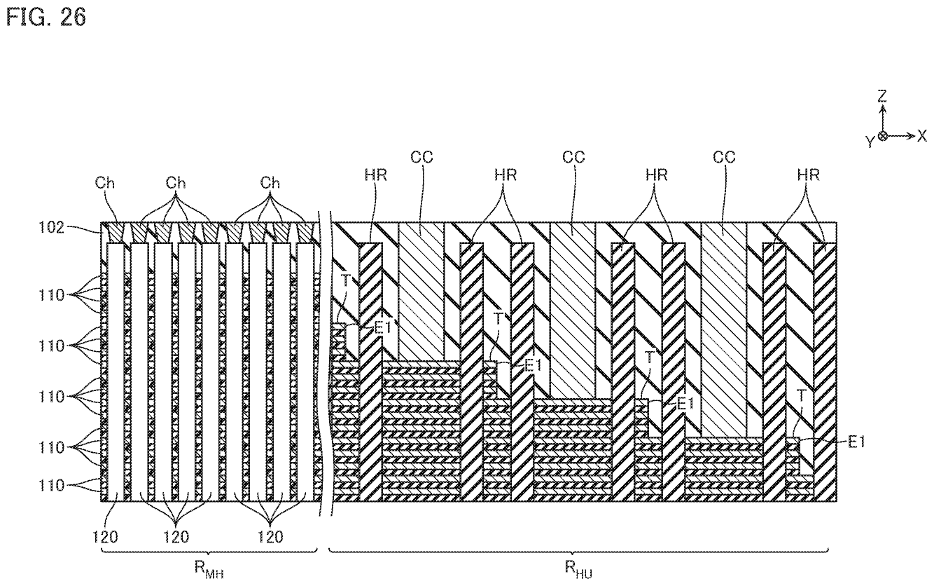

FIG. 26 is a schematic cross-sectional view illustrating a configuration of a semiconductor memory device according to a comparative example. In the semiconductor memory device according to the comparative example, none of the supporting insulating members HR overlap with the via-contact electrodes CC when viewed from the Z-direction.

In a manufacturing of the semiconductor memory device according to the comparative example, in the process described with reference to FIG. 22 and FIG. 23, the plurality of contact holes CCA are formed avoiding the plurality of supporting insulating members HR. In addition, in the manufacturing of the semiconductor memory device according to the comparative example, the process described with reference to FIG. 24 and FIG. 25 is not performed.

Here, the process described with reference to FIG. 22 and FIG. 23 (the process of forming the contact holes CCA) is performed under a condition in which materials such as silicon oxide (SiO₂) constituting the insulating layer 102 are relatively easy to be removed, and materials such as titanium nitride (TiN) and tungsten (W) constituting the conductive layers 110 are relatively difficult to be removed. Therefore, when only the conductive layers 110 are exposed on the bottom surfaces of the contact holes CCA, lower end positions of the contact holes CCA can be relatively preferably controlled.

However, similarly to the insulating layer 102, the supporting insulating members HR are formed of materials such as silicon oxide (SiO₂). Therefore, when not only the conductive layers 110 but also the supporting insulating members HR are exposed on the bottom surfaces of the contact holes CCA, the contact holes CCA are formed even below the corresponding conductive layers 110, which may possibly lead to short-circuits between the conductive layers 110.

In order to avoid such phenomenon, it is also considerable to, for example, dispose the supporting insulating members HR at positions sufficiently apart from the contact holes CCA. However, if the distances between the supporting insulating members HR are increased, the insulating layers 101 may possibly bend in a process corresponding to FIG. 19 in some cases.

In addition, in association with high integration of the semiconductor memory device, the number of the conductive layers 110 arranged in the Z-direction is increasing, and an aspect ratio of the contact hole CCA described with reference to FIG. 23 is also increasing. As a result, when forming the contact holes CCA, there occurs a possibility that the RIE proceeds in a direction inclined with respect to the Z-direction, the contact holes CCA are formed obliquely, and the supporting insulating members HR are exposed on the bottom surfaces of the contact holes CCA.

### Effect of First Embodiment

In the manufacturing of the semiconductor memory device according to the embodiment, in the process described with reference to FIG. 23, a part of the supporting insulating members HR are removed. In addition, in the process described with reference to FIG. 24, the via holes HRA corresponding to the removed supporting insulating members HR are embedded by the insulating layer CCSWA. Further, in the process described with reference to FIG. 25, the insulating layer CCSWA is partially removed to expose the terrace portions T.

With such method, since the via holes HRA are embedded by the insulating layer CCSWA in the process described with reference to FIG. 24, the short-circuits between the conductive layers 110 as described above can be preferably reduced even when the supporting insulating members HR are exposed on the bottom surfaces of the contact holes CCA. Therefore, an arrangement of the supporting insulating members HR is adjustable independently from an arrangement of the via-contact electrodes CC, and for example, in the process described with reference to FIG. 19, the supporting insulating members HR can be densely arranged to the extent that the insulating layers 101 do not bend. Further, it is also possible to employ an arrangement in which the via-contact electrode CC and the supporting insulating member HR1 overlap such that the entire outer peripheral surface of the supporting insulating member HR1 when viewed from the Z-direction is positioned inside the outer peripheral surface of the via-contact electrode CC at a position on the lower surface of the via-contact electrode CC in contact with the conductive layer 110 and the supporting insulating member HR1.

### Second Embodiment

As described with reference to FIG. 5 to FIG. 7, in the first embodiment, when viewed from the Z-direction, one via-contact electrode CC overlaps with one supporting insulating member HR. However, such configuration is merely an example, and one via-contact electrode CC may overlap with a plurality of the supporting insulating members HR when viewed from the Z-direction. Even in such configuration, an effect similar to that of the first embodiment can be provided. Further, a contacted area between the via-contact electrode CC and the conductive layer 110 can be increased to decrease contact resistance. Such configuration is exemplified in the following.

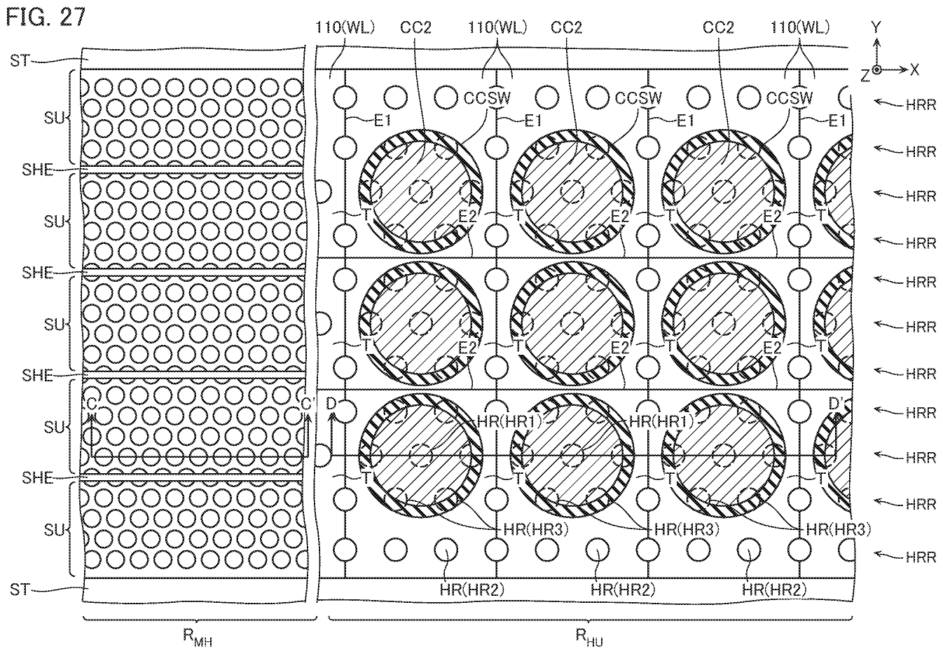

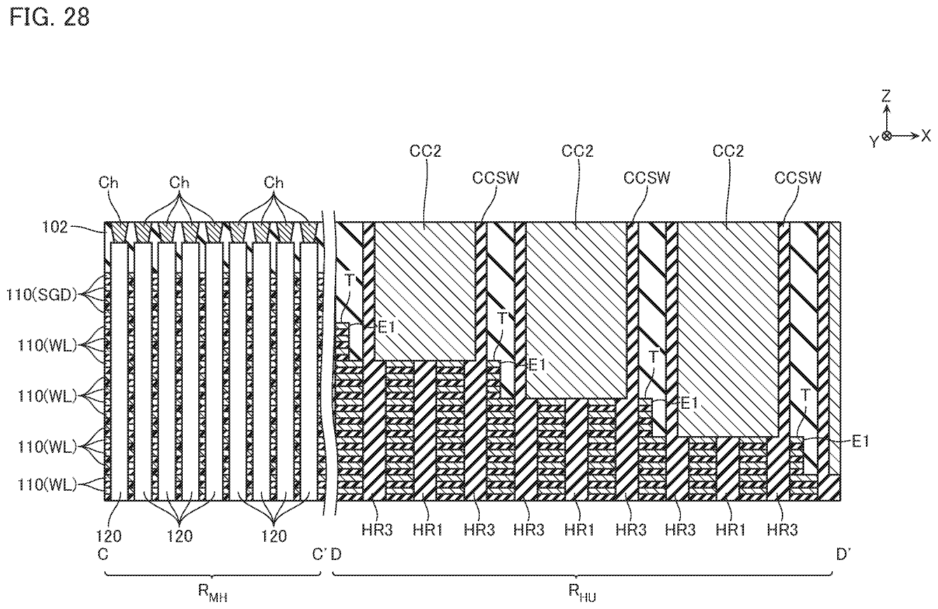

FIG. 27 is a schematic plan view illustrating a configuration of a semiconductor memory device according to the second embodiment. FIG. 28 is a schematic cross-sectional view of the structure illustrated in FIG. 27 taken along a line C-C″ and a line D-D″ and viewed in an arrow direction.

The semiconductor memory device according to the second embodiment is basically configured similarly to the semiconductor memory device according to the first embodiment.

However, in FIG. 27, supporting insulating members HR3 are exemplified in addition to the supporting insulating members HR1 and supporting insulating members HR2 as the plurality of supporting insulating members HR. The respective via-contact electrodes CC2 according to the second embodiment overlap with a plurality (seven in the illustrated example) of the supporting insulating members HR (one supporting insulating member HR1 and six supporting insulating members HR3).

As illustrated in FIG. 27, the supporting insulating member HR3 has a part overlapping with the via-contact electrode CC2 and a part not overlapping with the via-contact electrode CC2 when viewed from the Z-direction. Therefore, at a position on a lower surface of the via-contact electrode CC2 in contact with the conductive layer 110 and the supporting insulating member HR, an outer peripheral surface of the via-contact electrode CC2 and an outer peripheral surface of the supporting insulating member HR3 intersect with one another when viewed from the Z-direction. Further, when viewed from the Z-direction, a center position of the supporting insulating member HR3 does not overlap (does not approximately coincide) with a center position of any of the via-contact electrodes CC2.

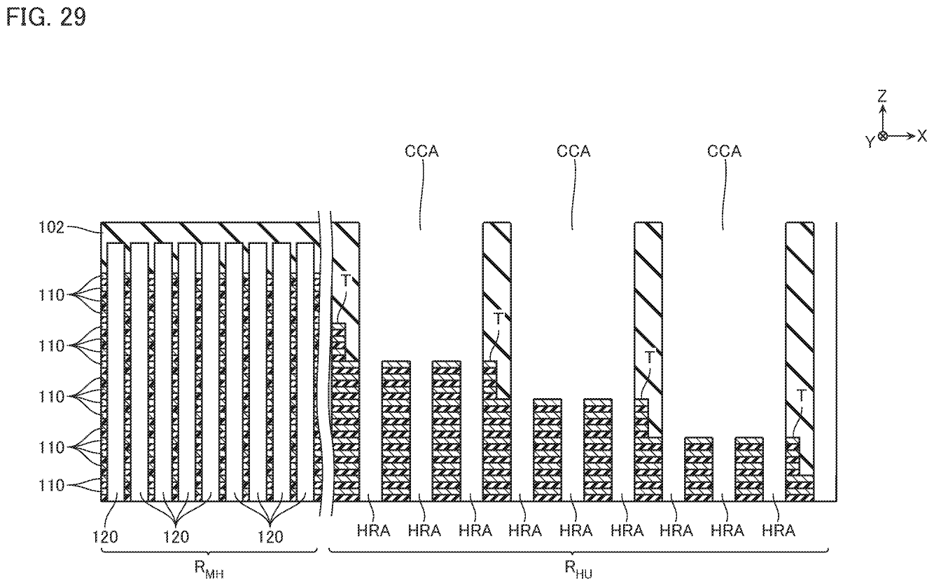

Next, a manufacturing method of the semiconductor memory device according to the second embodiment will be described with reference to FIG. 29 to FIG. 31. FIG. 29 to FIG. 31 are schematic cross-sectional views for describing the manufacturing method, and illustrate a cross-sectional surface corresponding to FIG. 28.

The semiconductor memory device according to the second embodiment is basically manufactured similarly to the semiconductor memory device according to the first embodiment.

However, in the manufacturing method according to the first embodiment, in the manufacturing process described with reference to FIG. 23, one supporting insulating member HR is exposed on the bottom surface of each contact hole CCA, and such supporting insulating members HR are removed.

On the other hand, in the manufacturing method according to the second embodiment, in a process corresponding to FIG. 23, as illustrated in FIG. 29, a plurality (seven in the illustrated example) of the supporting insulating members HR are exposed on the bottom surface of each contact hole CCA, and such supporting insulating members HR are removed.

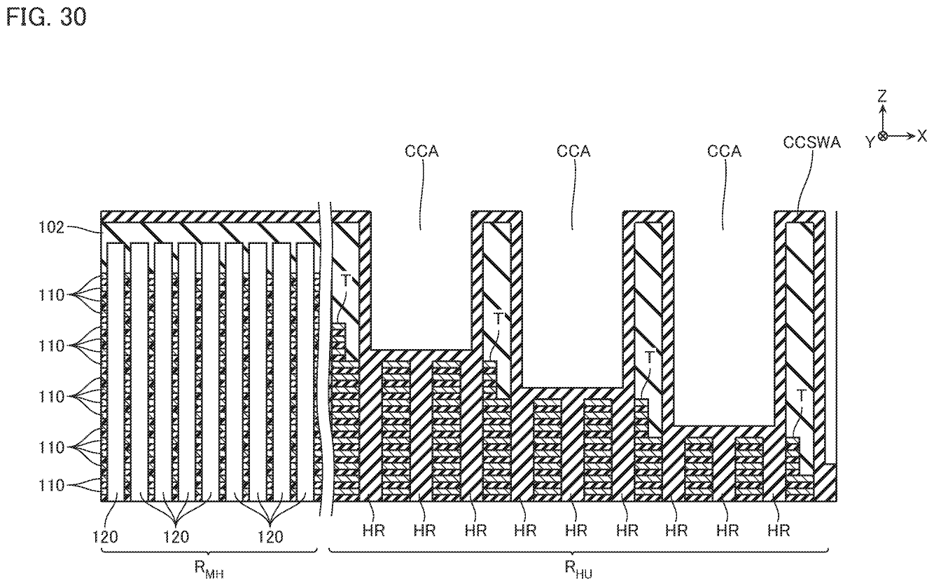

In addition, in a process corresponding to FIG. 24, as illustrated in FIG. 30, the insulating layer CCSWA is embedded into a plurality (seven in the illustrated example) of the via holes HRA inside each contact hole CCA.

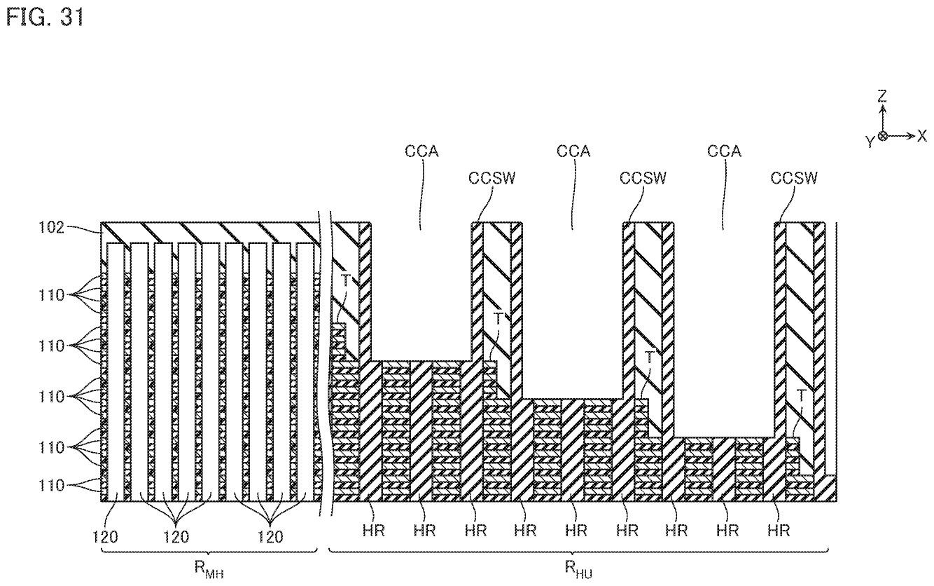

In addition, in a process corresponding to FIG. 25, as illustrated in FIG. 31, similarly to the first embodiment, the parts of the insulating layer CCSWA formed on the bottom surfaces of the contact holes CCA are removed to expose the terrace portions T.

### Third Embodiment

As described with reference to FIG. 5 to FIG. 7, in the first embodiment and the second embodiment, when viewed from the Z-direction, the center positions of the via-contact electrodes CC, CC2 overlap (approximately coincide) with the center position of the supporting insulating member HR1. However, since the positioning of the via holes HRA described with reference to FIG. 12 and the positioning of the contact holes CCA described with reference to FIG. 23 are performed in different processes, the center positions of the via-contact electrodes CC, CC2 and the center positions of the supporting insulating members HR do not overlap (do not approximately coincide) when viewed from the Z-direction in some cases. Further, in order for the via-contact electrodes CC, CC2 and the conductive layer 110 to be brought into contact, the center positions of the via-contact electrodes CC, CC2 and the center positions of the supporting insulating members HR need not overlap (need not approximately coincide) when viewed from the Z-direction. Even in such configuration, an effect similar to that of the first embodiment and the second embodiment can be provided. The following exemplifies such configuration.

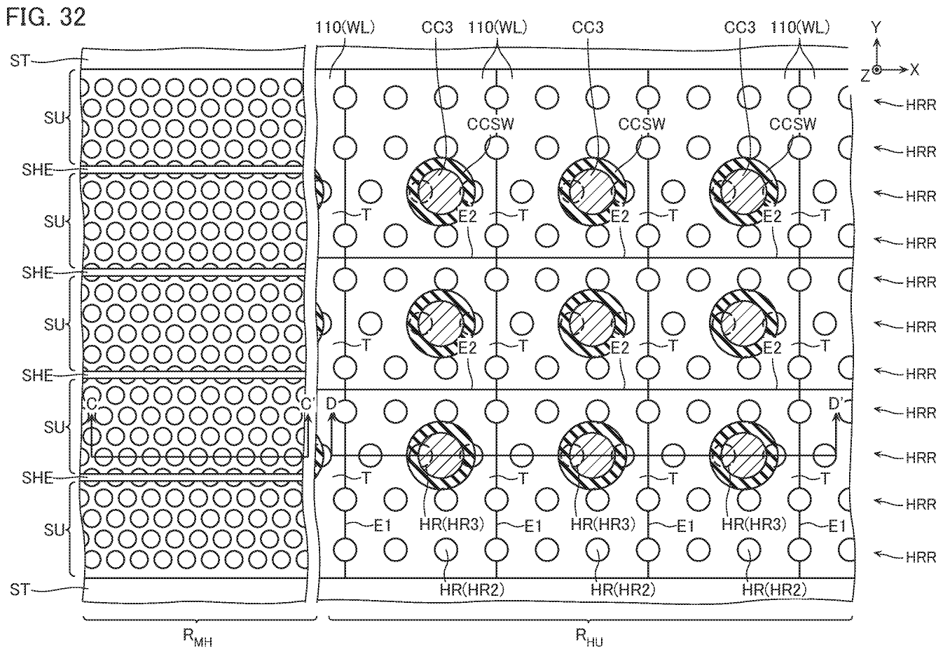

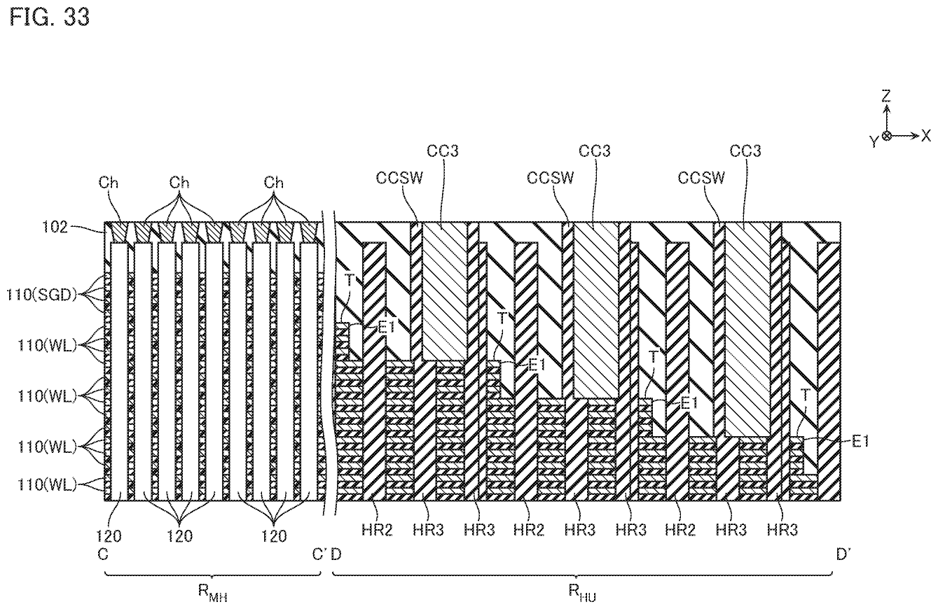

FIG. 32 is a schematic plan view illustrating a configuration of a semiconductor memory device according to a third embodiment. FIG. 33 is a schematic cross-sectional view of the structure illustrated in FIG. 32 taken along a line C-C″ and a line D-D′ and viewed in an arrow direction.

The semiconductor memory device according to the third embodiment is basically configured similarly to the semiconductor memory device according to the first embodiment.

However, center positions of the via-contact electrodes CC3 according to the third embodiment do not overlap (does not approximately coincide) with center positions of any of the supporting insulating members HR when viewed from the Z-direction.

In the third embodiment, the via-contact electrode CC3 may overlap with only one supporting insulating member HR when viewed from the Z-direction, or may overlap with two or more supporting insulating members HR.

Note that, in FIG. 32, the supporting insulating members HR2 and the supporting insulating members HR3 are exemplified as the plurality of supporting insulating members HR.

However, for example, a plurality of the via-contact electrodes CC, CC2 may include both of those that overlap with the center position of any of the supporting insulating members HR and those that do not overlap with the center position of any of the supporting insulating members HR. For example, the semiconductor memory device according to the first embodiment may include the via-contact electrodes CC3 and the supporting insulating members HR3 in addition to the via-contact electrodes CC and the supporting insulating members HR1.

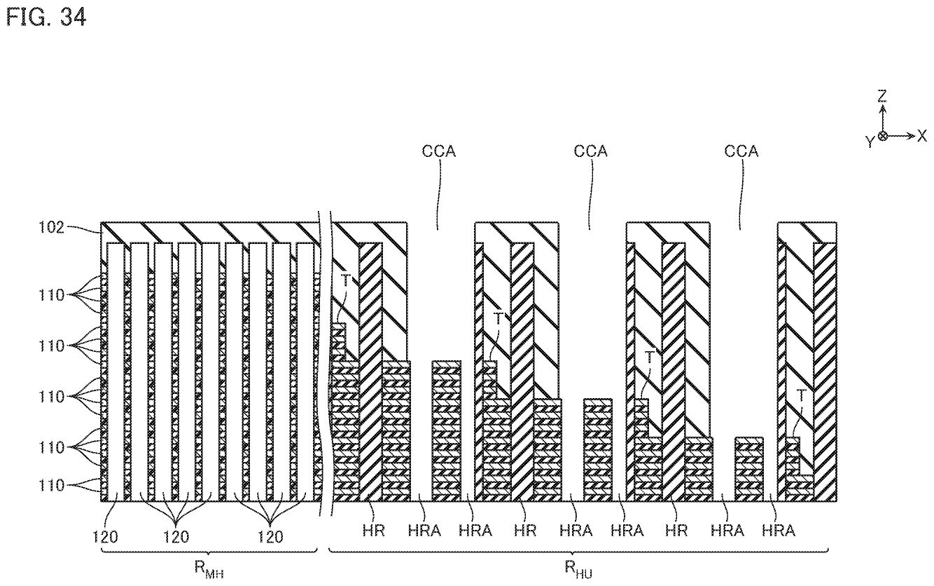

Next, a manufacturing method of the semiconductor memory device according to the third embodiment will be described with reference to FIG. 34 to FIG. 36. FIG. 34 to FIG. 36 are schematic cross-sectional views for describing the manufacturing method, and illustrate a cross-sectional surface corresponding to FIG. 33.

The semiconductor memory device according to the third embodiment is basically manufactured similarly to the semiconductor memory device according to the first embodiment.

However, in the manufacturing method according to the first embodiment, in the process described with reference to FIG. 23, the central axis of each contact hole CCA approximately coincides with the central axis of any of the supporting insulating members HR.

On the other hand, in the manufacturing method according to the third embodiment, in a process corresponding to FIG. 23, as illustrated in FIG. 34, the central axis of each contact hole CCA does not approximately coincide with the central axis of any of the supporting insulating members HR. In the illustrated example, a part of the supporting insulating members HR have a part that overlaps with the contact hole CCA when viewed from the Z-direction, and a part that does not overlap with the contact hole CCA when viewed from the Z-direction, and only the former is removed.

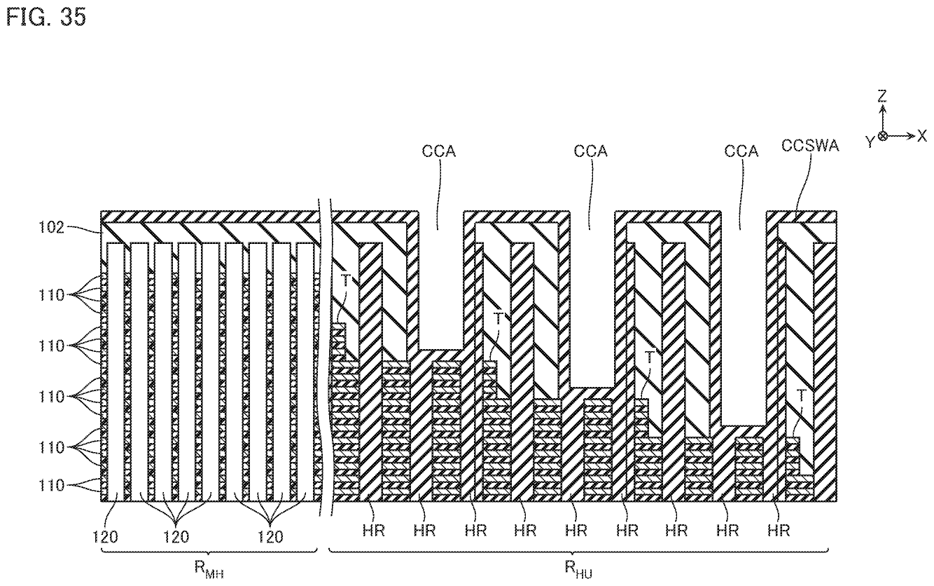

Further, in a process corresponding to FIG. 24, as illustrated in FIG. 35, the insulating layer CCSWA is embedded into the via hole HRA inside each contact hole CCA.

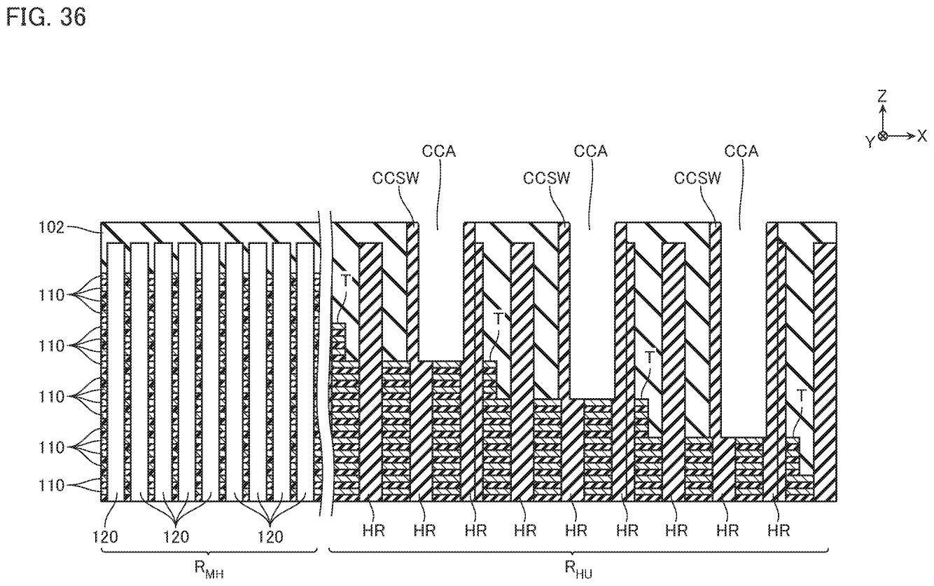

Next, in a process corresponding to FIG. 25, as illustrated in FIG. 36, similarly to the first embodiment, the parts of the insulating layer CCSWA formed on the bottom surfaces of the contact holes CCA are removed to expose the terrace portions T.

### Other Embodiments

The configurations of the semiconductor memory device according to the first embodiment to the third embodiment have been described above. However, the configurations exemplified above are merely examples and a specific configuration is appropriately adjustable.

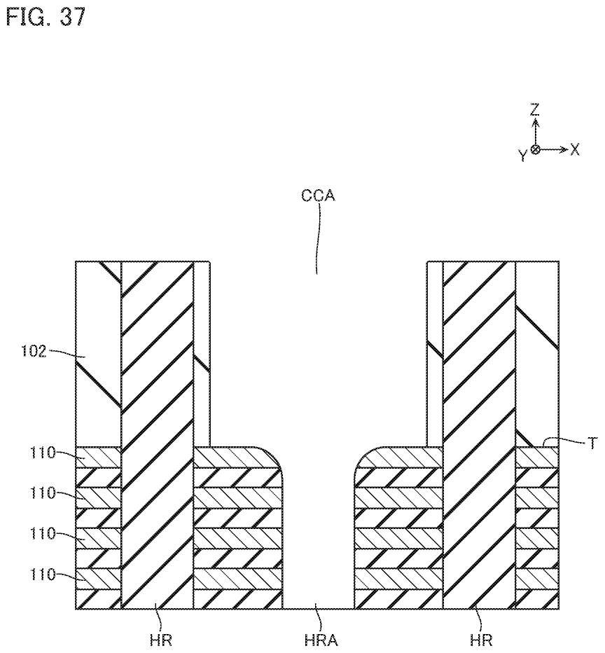

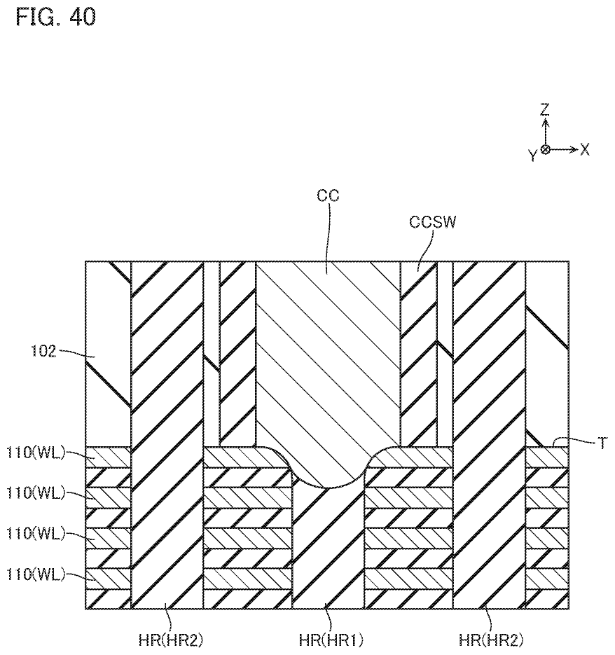

FIG. 37 to FIG. 39 are schematic cross-sectional views illustrating a manufacturing method of a semiconductor memory device according to another embodiment. FIG. 40 is a schematic cross-sectional view illustrating a configuration of the semiconductor memory device according to the other embodiment.

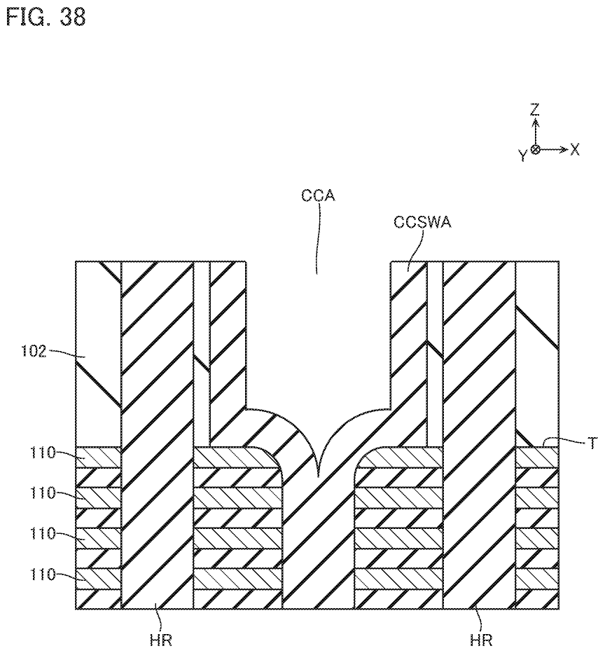

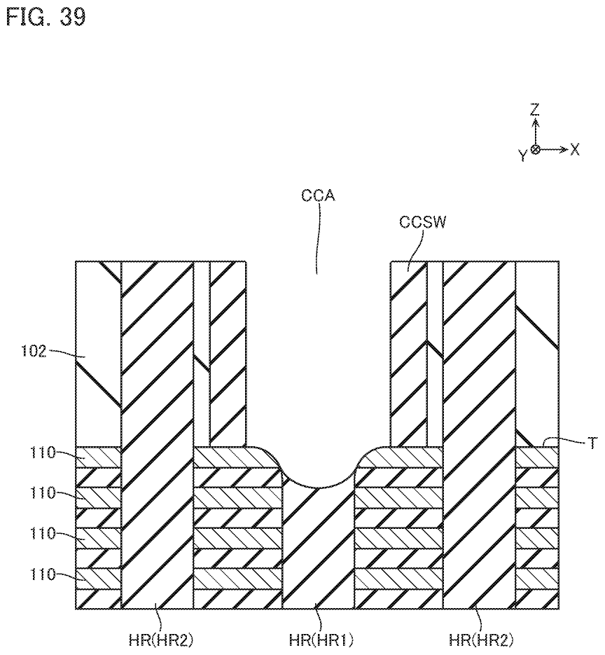

In the manufacturing methods according to the first embodiment to the third embodiment, in the process described with reference to FIG. 23 or a process corresponding to the process described with reference to FIG. 23, as exemplified in FIG. 37, for example, a curved surface continuously made by an inner peripheral surface of the via hole HRA and the bottom surface of the contact hole CCA may be formed. In such method, as in the illustrated example, a port of the via hole HRA expands. Accordingly, in the process described with reference to FIG. 24, as illustrated in FIG. 38, the insulating layer CCSW can be appropriately embedded into the via hole HRA. Note that, in the illustrated example, in the process described with reference to FIG. 25, as illustrated in FIG. 39, the curved surface described above is exposed on the bottom surface of the contact hole CCA.

As a result, as illustrated in FIG. 40, in the semiconductor memory device manufactured by such method, a curved surface protruding toward the via-contact electrode CC side is formed on the contact surface in contact with the conductive layer 110 of the lower surface of the via-contact electrode CC.

Note that, FIG. 40 illustrated an example in which the curved surface protruding toward the via-contact electrode CC side is formed on the contact surface between the via-contact electrode CC and the conductive layer 110 in the semiconductor memory device according to the first embodiment. However, curved surfaces that are convex toward the via-contact electrode CC2, CC3 sides may be formed on contact surfaces between the via-contact electrodes CC2, CC3 and the conductive layer 110 in the semiconductor memory device according to the second embodiment or the third embodiment.

In addition, in the semiconductor memory devices according to the first embodiment to the third embodiment, as described above, a conductive member or a semiconductor member is not disposed inside the through holes corresponding to the supporting insulating members HR of the conductive layers 110, and only an insulating member is disposed therein. In the semiconductor memory devices according to the first embodiment to the third embodiment, even when a structure as exemplified in FIG. 40 is employed, a conductive member or a semiconductor member is basically not disposed inside the through holes corresponding to the supporting insulating members HR of the conductive layers 110. However, among the through holes of the conductive layers 110, inside those that overlap with the via-contact electrodes CC connected to these conductive layers 110 when viewed from the Z-direction, a part of the via-contact electrode CC is disposed as a conductive member in some cases, as exemplified in FIG. 40. Note that, a conductive member or a semiconductor member is not disposed in at least the through holes corresponding to the supporting insulating members HR2 among the through holes of the conductive layers 110.

Further, the semiconductor memory device according to the first embodiment is manufactured by forming the peripheral circuit on the upper surface of the semiconductor wafer, and performing processes described with reference to FIG. 8 to FIG. 25 on this semiconductor wafer. However, the processes described with reference to FIG. 8 to FIG. 25 may be performed on another wafer other than the semiconductor wafer on which the peripheral circuit is formed. For example, it may be as follows: the peripheral circuit is formed on a first wafer; the processes described with reference to FIG. 8 to FIG. 25 are performed on a second wafer; the first wafer and the second wafer are bonded together; and the second wafer is removed. The same applies to the semiconductor memory devices according to the second embodiment and the third embodiment.

[Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a substrate including a first region and a second region arranged in a first direction;
a plurality of conductive layers stacked in a stacking direction intersecting with a surface of the substrate, and extending in the first direction across the first region and the second region;
a semiconductor layer disposed in the first region, extending in the stacking direction, and opposed to the plurality of conductive layers;
an electric charge accumulating film disposed between the plurality of conductive layers and the semiconductor layer;
a plurality of contact electrodes disposed in the second region, and connected to a plurality of terrace portions of the plurality of conductive layers arranged in the first direction via parts of outer edges of the plurality of conductive layers when viewed from the stacking direction; and
a plurality of insulating members disposed in the second region, and including outer peripheral surfaces surrounded by at least a part of the plurality of conductive layers when viewed from the stacking direction, wherein
the plurality of insulating members include:
a first insulating member that overlaps with a first contact electrode of the plurality of contact electrodes when viewed from the stacking direction; and
a second insulating member that does not overlap with any of the plurality of contact electrodes when viewed from the stacking direction,
a surface on one side in the stacking direction of the first contact electrode includes a contact surface in contact with a first conductive layer of the plurality of conductive layers, and a contact surface in contact with the first insulating member, and
insides of surfaces surrounding the second insulating member of at least a part of the plurality of conductive layers when viewed from the stacking direction are not provided with a conductive member or a semiconductor member.

2. The semiconductor memory device according to claim 1, wherein
a center position of the first contact electrode in a cross-sectional surface perpendicular to the stacking direction and including the first contact electrode is a first center position,
a center position of the first insulating member in a cross-sectional surface perpendicular to the stacking direction, and including the first insulating member and one of the plurality of conductive layers surrounding an outer peripheral surface of the first insulating member is a second center position, and
the first center position does not overlap with the second center position when viewed from the stacking direction.

3. The semiconductor memory device according to claim 1, wherein
a length in the first direction of the surface on the one side in the stacking direction of the first contact electrode is a first length,
a length in the first direction of the first insulating member at a position in the stacking direction corresponding to a conductive layer that is closest to the first contact electrode among the plurality of conductive layers surrounding an outer peripheral surface of the first insulating member is a second length, and
the first length is larger than the second length.

4. The semiconductor memory device according to claim 1, wherein
the plurality of insulating members further include a third insulating member that overlaps with the first contact electrode when viewed from the stacking direction.

5. The semiconductor memory device according to claim 4, wherein
the surface on the one side in the stacking direction of the first contact electrode further includes a contact surface in contact with the third insulating member.

6. The semiconductor memory device according to claim 1, wherein
in a cross-sectional surface extending in the stacking direction and the first direction, and including the first conductive layer, the first contact electrode, and the first insulating member, the contact surface of the first contact electrode in contact with the first conductive layer includes a curved surface protruding toward a side of the first contact electrode.

7. The semiconductor memory device according to claim 1, further comprising
a high-dielectric-constant insulating layer disposed between at least a part of the plurality of conductive layers and one of the plurality of insulating members.

8. A semiconductor memory device comprising:
a substrate including a first region and a second region arranged in a first direction;
a plurality of conductive layers stacked in a stacking direction intersecting with a surface of the substrate, and extending in the first direction across the first region and the second region;
a semiconductor layer disposed in the first region, extending in the stacking direction, and opposed to the plurality of conductive layers;
an electric charge accumulating film disposed between the plurality of conductive layers and the semiconductor layer;
a plurality of contact electrodes disposed in the second region, and connected to a plurality of terrace portions of the plurality of conductive layers arranged in the first direction via parts of outer edges of the plurality of conductive layers when viewed from the stacking direction; and
a plurality of insulating members disposed in the second region, and including outer peripheral surfaces surrounded by at least a part of the plurality of conductive layers when viewed from the stacking direction, wherein
at least two insulating members of the plurality of insulating members overlap with a first contact electrode of the plurality of contact electrodes when viewed from the stacking direction.

9. The semiconductor memory device according to claim 8, wherein
a center position of the first contact electrode in a cross-sectional surface perpendicular to the stacking direction and including the first contact electrode is a first center position, and
the first center position does not overlap with either of at least two center positions when viewed from the stacking direction, the at least two second center positions corresponding to respective center positions of the at least two insulating members in a cross-sectional surface perpendicular to the stacking direction, and including the at least two insulating members and one of the plurality of conductive layers surrounding outer peripheral surfaces of the at least two insulating members.

10. The semiconductor memory device according to claim 8, wherein
the at least two insulating members include a first insulating member,
a length in the first direction of a surface on a side of the first insulating member in the stacking direction of the first contact electrode is a first length,
a length in the first direction of the first insulating member at a position in the stacking direction corresponding to a conductive layer that is closest to the first contact electrode among the plurality of conductive layers surrounding an outer peripheral surface of the first insulating member is a second length, and
the first length is larger than the second length.

11. The semiconductor memory device according to claim 9, wherein
a surface on one side in the stacking direction of the first contact electrode includes a contact surface in contact with a first conductive layer of the plurality of conductive layers, and contact surfaces in contact with the at least two insulating members.

12. The semiconductor memory device according to claim 11, wherein
the at least two insulating members include a first insulating member, and
an outer peripheral surface of the first insulating member at a position in the stacking direction corresponding to a contact surface of the first insulating member in contact with the first contact electrode is positioned inside an outer peripheral surface of the first contact electrode at a position in the stacking direction corresponding to the surface on the one side in the stacking direction of the first contact electrode when viewed from the stacking direction.

13. The semiconductor memory device according to claim 11, wherein
an outer peripheral surface of the first contact electrode at a position in the stacking direction corresponding to the surface on the one side in the stacking direction of the first contact electrode intersects with each of at least two outer peripheral surfaces of the at least two insulating members at a position in the stacking direction corresponding to contact surfaces of the at least two insulating members in contact with the first contact electrode when viewed from the stacking direction.

14. The semiconductor memory device according to claim 11, wherein
the at least two insulating members include a first insulating member, and
in a cross-sectional surface extending in the stacking direction and the first direction, and including the first conductive layer, the first contact electrode, and the first insulating member, the contact surface of the first contact electrode in contact with the first conductive layer includes a curved surface protruding toward a side of the first contact electrode.

15. The semiconductor memory device according to claim 8, further comprising
a high-dielectric-constant insulating layer disposed between at least a part of the plurality of conductive layers and one of the plurality of insulating members.

16. A semiconductor memory device comprising:
a substrate including a first region and a second region arranged in a first direction;
a plurality of conductive layers stacked in a stacking direction intersecting with a surface of the substrate, and extending in the first direction across the first region and the second region;
a semiconductor layer disposed in the first region, extending in the stacking direction, and opposed to the plurality of conductive layers;
an electric charge accumulating film disposed between the plurality of conductive layers and the semiconductor layer;
a plurality of contact electrodes disposed in the second region, and connected to a plurality of terrace portions of the plurality of conductive layers arranged in the first direction via parts of outer edges of the plurality of conductive layers when viewed from the stacking direction; and
a plurality of insulating members disposed in the second region, and including outer peripheral surfaces surrounded by at least a part of the plurality of conductive layers when viewed from the stacking direction, wherein
the plurality of insulating members include a first insulating member that overlaps with a first contact electrode of the plurality of contact electrodes when viewed from the stacking direction,
a center position of the first contact electrode in a cross-sectional surface perpendicular to the stacking direction and including the first contact electrode is a first center position,
a center position of the first insulating member in a cross-sectional surface perpendicular to the stacking direction, and including the first insulating member and one of the plurality of conductive layers surrounding an outer peripheral surface of the first insulating member is a second center position, and
the first center position does not overlap with the second center position when viewed from the stacking direction.

17. The semiconductor memory device according to claim 16, wherein
a length in the first direction of a surface on a side of the first insulating member in the stacking direction of the first contact electrode is a first length,
a length in the first direction of the first insulating member at a position in the stacking direction corresponding to a conductive layer that is closest to the first contact electrode among the plurality of conductive layers surrounding an outer peripheral surface of the first insulating member is a second length, and
the first length is larger than the second length.

18. The semiconductor memory device according to claim 16, wherein
a surface on one side in the stacking direction of the first contact electrode includes a contact surface in contact with a first conductive layer of the plurality of conductive layers, and a contact surface in contact with the first insulating member.

19. The semiconductor memory device according to claim 18, wherein
in a cross-sectional surface extending in the stacking direction and the first direction, and including the first conductive layer, the first contact electrode, and the first insulating member, the contact surface of the first contact electrode in contact with the first conductive layer includes a curved surface protruding toward a side of the first contact electrode.

20. The semiconductor memory device according to claim 16, further comprising
a high-dielectric-constant insulating layer disposed between at least a part of the plurality of conductive layers and one of the plurality of insulating members.
